(19) United States
(12) Patent Application Publication
(10) Pub. No.: US 2026/0128717 A1
(43) Pub. Date: May 7, 2026

(54) LOW NOISE AMPLIFIER AND ELECTRONIC DEVICE USING LOW NOISE AMPLIFIER IN WIRELESS COMMUNICATION SYSTEM

(71) Applicant: SAMSUNG ELECTRONICS CO., LTD., Suwon-si (KR)

(72) Inventors: Jinhyun Kim, Suwon-si (KR); Kihyun Kim, Suwon-si (KR); Bohee Suh, Suwon-si (KR)

(73) Assignee: SAMSUNG ELECTRONICS CO., LTD., Suwon-si (KR)

(21) Appl. No.: 19/335,778

(22) Filed: Sep. 22, 2025

Related U.S. Application Data
(63) Continuation of application No. PCT/KR2025/014368, filed on Sep. 16, 2025.

(30) Foreign Application Priority Data
Nov. 6, 2024 (KR) 10-2024-0156304

(51) Int. Cl. H03F 1/26; H03F 3/21; H03F 3/213; H04B 1/04; H04L 5/00

(52) U.S. Cl. CPC H03F 1/26; H03F 3/211; H03F 3/213; H04B 1/04; H04L 5/0048; H03F 2200/06; H03F 2200/294; H03F 2200/451

(57) ABSTRACT

A low noise amplifier (LNA) in a wireless communication system includes a first amplifier including a first transistor and configured to amplify a first input signal based on a first gain to generate a first output signal, a second amplifier including a plurality of second transistors and configured to amplify a second input signal based on a second gain to generate a second output signal, and a balun coupled between the first amplifier and the second amplifier, and configured to input the first output signal and to output the second input signal. The balun includes a first inductor, a second inductor, and a third inductor. The third inductor is coupled with sources of the plurality of second transistors.

### CROSS-REFERENCE TO RELATED APPLICATIONS

This application is a continuation application of International Application No. PCT/KR2025/014368, filed on Sep. 16, 2025, which claims priority to Korean Patent Application No. 10-2024-0156304, filed on Nov. 6, 2024, in the Korean Intellectual Property Office, the disclosures of which are incorporated by reference herein in their entireties.

### BACKGROUND

### 1. Field

The present disclosure relates generally to wireless communication systems, and more particularly, to a low noise amplifier (LNA) and an electronic device using the LNA in a wireless communication system.

### 2. Description of Related Art

Wireless communication technologies may have been developed to provide services, such as, but not limited to, voice, multimedia, and/or data communications. For example, using 5th-generation (5G) communication systems that may be commercially available, deployment of connected devices may be expected to significantly increase, as well as, the number of devices connected to a communication network. Examples of devices connected to a network may include, but not be limited to, vehicles, robots, drones, home appliances, displays, smart sensors installed in various infrastructures, construction machinery, factory equipment, or the like. Mobile devices may evolve into various form factors, such as, but not limited to, augmented reality (AR) glasses, virtual reality (VR) headsets, hologram devices, or the like. As part of development in a subsequent generation of communication systems (e.g., 6th-generation (6G)), efforts may be being made to develop an enhanced communication system that may provide various services by connecting far greater numbers of devices (e.g., hundreds of billions of devices). Consequently, a 6G communication system may be referred to as a beyond 5G system.

In a 6G communication system that may be realized in the near future, maximum transmission rates in the range of one (1) tera bit per second (bps) (e.g., 1,000 gigabits per second (gbps)) and/or wireless latencies of about 100 microseconds (usec) may be achieved. That is, transmission rates of a 6G communication system may be approximately 50 times faster than transmission rates of a 5G communication system, and/or the wireless latency of a 6G communication system may be reduced to approximately one tenth (e.g., 1/10) of the wireless latency of a 5G communication system.

To potentially achieve these relatively high data rates and/or relatively low latencies, 6G communication systems may be considered to be implemented in terahertz bands (e.g., 95 gigahertz (GHz) to 3 terahertz (THz) bands). However, as path loss and/or atmospheric absorption issues may worsen in the terahertz band as compared with millimeter wave (mmWave) bands introduced in 5G communication systems, technologies and/or techniques that may guarantee and/or improve signal reach (e.g., coverage) may become more important. Possible techniques for ensuring and/or improving coverage may be directed to multi-antenna transmission techniques, such as, but not limited to, new waveform, beamforming, massive multiple-input and multiple-output (MIMO), full dimensional MIMO (FD-MIMO), array antennas, and/or large-scale antennas, which may exhibit better coverage characteristics than radio frequency (RF) devices and orthogonal frequency division multiplexing (OFDM). New technologies, such as, but not limited to, a metamaterial-based lens and antennas, high-dimensional spatial multiplexing technology using an orbital angular momentum (OAM), and a reconfigurable intelligent surface (RIS), may also be being discussed to potentially enhance coverage of the terahertz band signals.

6G communication systems may also potentially enhance frequency efficiency and/or the system network by including full-duplex technologies. That is, recent developments may include, but not be limited to, full-duplex technology in which uplink and downlink may simultaneously utilize the same frequency resource at the same time, network technology that may comprehensively use satellite and/or high-altitude platform stations (HAPSs), network architecture innovation technology that may enable optimization and/or automation of network operation and may support mobile base stations, dynamic spectrum sharing technology through collision avoidance based on prediction of spectrum usages, artificial intelligence (AI)-based communication technology that may use AI from the stage of designing and may internalize end-to-end AI supporting function to potentially optimize the system, and next-generation distributed computing technology that may realize services that may exceed the limitation of the UE computation capability by using ultra-high performance communication and mobile edge computing (MEC) and/or clouds. Further, attempts may have been made to reinforce connectivity between devices, further optimizing the network, prompting implementation of network entities in software, and/or increasing the openness of wireless communication by design of new protocols that may be used in 6G communication systems, implementation of hardware-based security environments, development of mechanisms for safely using data, and/or development of technology for maintaining and/or protecting privacy.

Such research and development efforts for 6G communication systems may implement the next hyper-connected experience via hyper-connectivity of 6G communication systems which may encompass human-thing connections as well as thing-to-thing connections. In particular, a 6G communication system may be able to provide services, such as, but not limited to, truly immersive extended reality (XR), high-fidelity mobile hologram, digital replicas, or the like. In addition, services, such as, but not limited to, remote surgery, industrial automation, emergency response, or the like may be provided through the 6G communication system due to enhanced security and reliability, as well as, various other applications in medical, auto, and/or home appliance industries, or the like.

A millimeter wave wireless communication system may be and/or may include a system that may significantly increase a data transmission speed and/or capacity using a millimeter wave band that may be a higher frequency band than a related radio frequency (RF) band. A millimeter wave signal may have relatively large path loss in a free space compared to a signal in a low frequency band (e.g., a frequency band lower than a threshold frequency) (e.g., path loss may exceed threshold path loss), Consequently, a millimeter wave wireless communication system may require relatively high effective isotropic radiated power (ERP), sensitivity, and/or wideband characteristics.

In a wireless communication system, a receiver may amplify an RF signal received via an antenna using a low noise amplifier (LNA). The LNA may be directly and/or indirectly connected to the antenna to reduce (e.g., minimize) additional noise of the RF signal received via the antenna, and amplify a relatively low power level of the received signal based on a set gain. Accordingly, development of technologies for enhancing a noise figure (NF) and/or a bandwidth characteristic of the LNA in a millimeter wave wireless communication system that may need relatively high reception sensitivity may have been continuously carried out. The NF may refer to an index indicating how much noise may be added while an input signal passes through a device and/or a circuit.

Generally, the LNA may include two (2) amplifiers, a first amplifier of the two amplifiers may be and/or may include a single-ended (SE) amplifier, and a second amplifier of the two amplifiers may be implemented to simultaneously obtain an NF and a wideband characteristic using relatively low input impedance. As such, a performance of the LNA may be significantly affected by an NF and a wideband characteristic of the second amplifier as well as the first amplifier. In order to reduce a magnitude of input impedance of the second amplifier, the second amplifier may be implemented as a differential amplifier by using a balun with a relatively large loss, and/or the second amplifier may be implemented as an SE amplifier similar to the first amplifier by using a resonance circuit using an inductor and a capacitor.

For example, the differential amplifier that may be used with the balun may not only improve an isolation characteristic by using a capacitor capable of cross-coupling, but may also have a relatively higher gain than an SE amplifier. However, in order to match output impedance of the SE amplifier with a relatively low value and input impedance of the differential amplifier with a relatively high value, a balun with a relatively low coupling factor k is used, which may potentially lead to degradation in a gain and an NF due to loss occurred in a matching process despite a high gain characteristic of the second (differential) amplifier. Further, an available bandwidth may be limited due to high loss of impedance matching which may occur between the first amplifier and the second amplifier.

Alternatively, the SE amplifier used with the resonance circuit may have a relatively low loss in the impedance matching between the first amplifier and the second amplifier, and consequently, there may be little to no limitation on the available bandwidth. However, a gain of the second amplifier may also relatively low, which may lead to degradation in the NF.

### SUMMARY

According to an aspect of the present disclosure, a low noise amplifier (LNA) in a wireless communication system includes a first amplifier including a first transistor and configured to amplify a first input signal based on a first gain to generate a first output signal, a second amplifier including a plurality of second transistors and configured to amplify a second input signal based on a second gain to generate a second output signal, and a balun coupled between the first amplifier and the second amplifier, and configured to input the first output signal and to output the second input signal. The balun includes a first inductor, a second inductor, and a third inductor. The third inductor is coupled with sources of the plurality of second transistors.

In an embodiment, the balun may further include a metal stack including a plurality of metal layers on a substrate.

In an embodiment, the first inductor, the second inductor, and the third inductor may be disposed on a first metal layer of the plurality of metal layers. The first inductor may be disposed at an outermost portion of the first metal layer among the first inductor, the second inductor, and the third inductor. The third inductor may be disposed at an innermost portion of the first metal layer among the first inductor, the second inductor, and the third inductor. The second inductor may be between the first inductor and the third inductor.

In an embodiment, the first inductor, the second inductor, and the third inductor may be disposed on a first metal layer of the plurality of metal layers. The second inductor may cross-coupled with gates of the plurality of second transistors.

In an embodiment, the first inductor, the second inductor, and the third inductor may be disposed on a first metal layer of the plurality of metal layers. The third inductor may be cross-coupled with the sources of the plurality of second transistors.

In an embodiment, the second inductor and the third inductor may be cross-coupled with the second amplifier.

In an embodiment, the third inductor may be coupled with a ground.

In an embodiment, the third inductor may be coupled with the first inductor.

In an embodiment, the balun may further include a power supply, and a capacitor coupled with the power supply.

In an embodiment, the first amplifier may include a single-ended amplifier, and the second amplifier may include a differential amplifier.

According to an aspect of the present disclosure, an electronic device in a wireless communication system includes an LNA including a first amplifier including a first transistor and configured to amplify a first input signal based on a first gain to generate a first output signal, a second amplifier including a plurality of second transistors and configured to amplify a second input signal based on a second gain to generate a second output signal, and a balun coupled between the first amplifier and the second amplifier, and configured to input the first output signal and to output the second input signal. The balun includes a first inductor, a second inductor, and a third inductor. The third inductor is coupled with sources of the plurality of second transistors.

In an embodiment, the balun may further include a metal stack including a plurality of metal layers on a substrate.

In an embodiment, the first inductor, the second inductor, and the third inductor may be disposed on a first metal layer of the plurality of metal layers. The first inductor may be disposed at an outermost portion of the first metal layer among the first inductor, the second inductor, and the third inductor. The third inductor may be disposed at an innermost portion of the first metal layer among the first inductor, the second inductor, and the third inductor. The second inductor may be between the first inductor and the third inductor.

In an embodiment, the first inductor, the second inductor, and the third inductor may be disposed on a first metal layer of the plurality of metal layers. The second inductor may be cross-coupled with gates of the plurality of second transistors.

In an embodiment, the first inductor, the second inductor, and the third inductor may be disposed on a first metal layer of the plurality of metal layers. The third inductor may be cross-coupled with the sources of the plurality of second transistors.

In an embodiment, the second inductor and the third inductor may be cross-coupled with the second amplifier.

In an embodiment, the third inductor may be coupled with a ground.

In an embodiment, the third inductor may be coupled with the first inductor.

In an embodiment, the balun may further include a power supply, and a capacitor coupled with the power supply.

In an embodiment, the first amplifier may include a single-ended amplifier, and the second amplifier may include a differential amplifier.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1A is a block diagram illustrating an electronic device in a network environment, according to an embodiment;

FIG. 1B is a block diagram schematically illustrating an electronic device, according to an embodiment;

FIG. 2 is a diagram schematically illustrating a low noise amplifier (LNA) in a wireless communication system, according to an embodiment;

FIG. 3 is a diagram schematically illustrating an LNA in a wireless communication system, according to an embodiment;

FIG. 4 is a diagram schematically illustrating a layout of a gₘ-coupled balun included in an LNA in a wireless communication system, according to an embodiment;

FIG. 5 is a diagram schematically illustrating an LNA in a wireless communication system, according to an embodiment;

FIG. 6A is a diagram schematically illustrating a layout of a first inductor included in a gₘ-coupled balun included in an LNA, according to an embodiment;

FIG. 6B is a diagram schematically illustrating a layout of a first inductor included in a gₘ-coupled balun included in an LNA, according to an embodiment;

FIG. 6C is a diagram schematically illustrating a layout of a first inductor included in a gₘ-coupled balun included in an LNA, according to an embodiment;

FIG. 7A is a diagram schematically illustrating a layout of a second inductor included in a gₘ-coupled balun included in an LNA, according to an embodiment;

FIG. 7B is a diagram schematically illustrating a layout of a second inductor included in a gₘ-coupled balun included in an LNA, according to an embodiment;

FIG. 7C is a diagram schematically illustrating a layout of a second inductor included in a gₘ-coupled balun included in an LNA, according to an embodiment;

FIG. 8A is a diagram schematically illustrating a layout of a third inductor included in a gₘ-coupled balun included in an LNA, according to an embodiment;

FIG. 8B is a diagram schematically illustrating a layout of a third inductor included in a gₘ-coupled balun included in an LNA, according to an embodiment;

FIG. 8C is a diagram schematically illustrating a layout of a third inductor included in a gₘ-coupled balun included in an LNA, according to an embodiment;

FIG. 9 is a diagram schematically illustrating an LNA in a wireless communication system, according to an embodiment;

FIG. 10 is a diagram schematically illustrating a layout of a gₘ-coupled balun included in an LNA in a wireless communication system, according to an embodiment;

FIG. 11 is a diagram schematically illustrating an LNA in a wireless communication system, according to an embodiment;

FIG. 12A is a diagram schematically illustrating a layout of a first inductor included in a gₘ-coupled balun included in an LNA, according to an embodiment;

FIG. 12B is a diagram schematically illustrating a layout of a first inductor included in a gₘ-coupled balun included in an LNA, according to an embodiment;

FIG. 12C is a diagram schematically illustrating a layout of a first inductor included in a gₘ-coupled balun included in an LNA, according to an embodiment;

FIG. 13A is a diagram schematically illustrating a layout of a second inductor included in a gₘ-coupled balun included in an LNA, according to an embodiment;

FIG. 13B is a diagram schematically illustrating a layout of a second inductor included in a gₘ-coupled balun included in an LNA, according to an embodiment;

FIG. 13C is a diagram schematically illustrating a layout of a second inductor included in a gₘ-coupled balun included in an LNA, according to an embodiment;

FIG. 14A is a diagram schematically illustrating a layout of a third inductor included in a gₘ-coupled balun included in an LNA, according to an embodiment;

FIG. 14B is a diagram schematically illustrating a layout of a third inductor included in a gₘ-coupled balun included in an LNA, according to an embodiment;

FIG. 14C is a diagram schematically illustrating a layout of a third inductor included in a gₘ-coupled balun included in an LNA, according to an embodiment;

FIG. 15 is a diagram illustrating an operation of an LNA in a wireless communication system, according to an embodiment;

FIG. 16 is a diagram illustrating an operation of an LNA in a wireless communication system, according to an embodiment;

FIG. 17 is a diagram illustrating a gain of an LNA in a wireless communication system, according to an embodiment; and

FIG. 18 is a diagram illustrating an NF of an LNA in a wireless communication system, according to an embodiment.

### DETAILED DESCRIPTION

Hereinafter, various embodiments of the present disclosure are described with reference to the accompanying drawings. In the following description, a detailed description of relevant known functions or configurations incorporated herein may be omitted if the description may make the subject matter of an embodiment unnecessarily unclear. The terms described below may be terms defined in consideration of the functions in the present disclosure, and may be different according to users, intentions of the users, or customs. Therefore, the definitions of the terms should be made based on the contents throughout the present disclosure.

It should be noted that the technical terms used herein are only used to describe a specific embodiment, and are not intended to limit an embodiment of the present disclosure. Alternatively, the technical terms used herein should be interpreted to have the same meaning as those commonly understood by a person skilled in the art to which the present disclosure pertains, and should not be interpreted have excessively comprehensive or excessively restricted meanings unless particularly defined as other meanings. Alternatively, when the technical terms used herein are wrong technical terms that cannot correctly represent the idea of the present disclosure, it should be appreciated that they are replaced by technical terms correctly understood by those skilled in the art. Alternatively, the general terms used in an embodiment of the present disclosure should be interpreted as defined in dictionaries or interpreted in the context of the relevant part, and should not be interpreted to have excessively restricted meanings.

Alternatively, a singular expression used herein may include a plural expression unless they are definitely different in the context. As used herein, such an expression as “comprises” or “include”, or the like should not be interpreted to necessarily include all elements or all operations described in the specification, and should be interpreted to be allowed to exclude some of them or further include additional elements or operations.

Alternatively, the terms including an ordinal number, such as expressions “a first” and “a second” may be used to describe various elements, but the corresponding elements should not be limited by such terms. These terms are used merely to distinguish between one element and any other element. For example, a first element may be termed a second element, and similarly, a second element may be termed a first element without departing from the scope of the present disclosure.

It is to be understood that when an element is referred to as being “connected” or “coupled” to another element, the element may be connected and/or coupled directly to the other element, or any other element may be interposer between them. In contrast, it is to be understood that when an element is referred to as being “directly connected” or “directly coupled” to another element, there are no element interposed between them.

Hereinafter, various embodiments of the present disclosure are described with reference to the accompanying drawings. Regardless of drawing signs, the same or like elements may be provided with the same reference numeral, and a repeated description thereof may be omitted for the sake of brevity. Alternatively, in describing an embodiment of the present disclosure, a description of relevant known technologies may be omitted if the description may make the subject matter of the present disclosure unclear. Alternatively, it is to be understood that the accompanying drawings are presented merely to help understanding of the technical idea of the present disclosure, and should not be construed to limit the technical idea of the present disclosure. The technical idea of the present disclosure may be construed to cover all changes, equivalents, and alternatives, in addition to the drawings.

Hereinafter, an electronic device is described as an example in an embodiment of the present disclosure. As used herein, the electronic device may be referred to as a terminal, a mobile station, a mobile equipment (ME), a user equipment (UE), a user terminal (UT), a subscriber station (SS), a wireless device, a handheld device, or an access terminal (AT). Alternatively or additionally, in an embodiment, the electronic device may be and/or may include a device having a communication function such as, for example, a mobile phone, a personal digital assistant (PDA), a smart phone, a wireless MODEM, or a notebook.

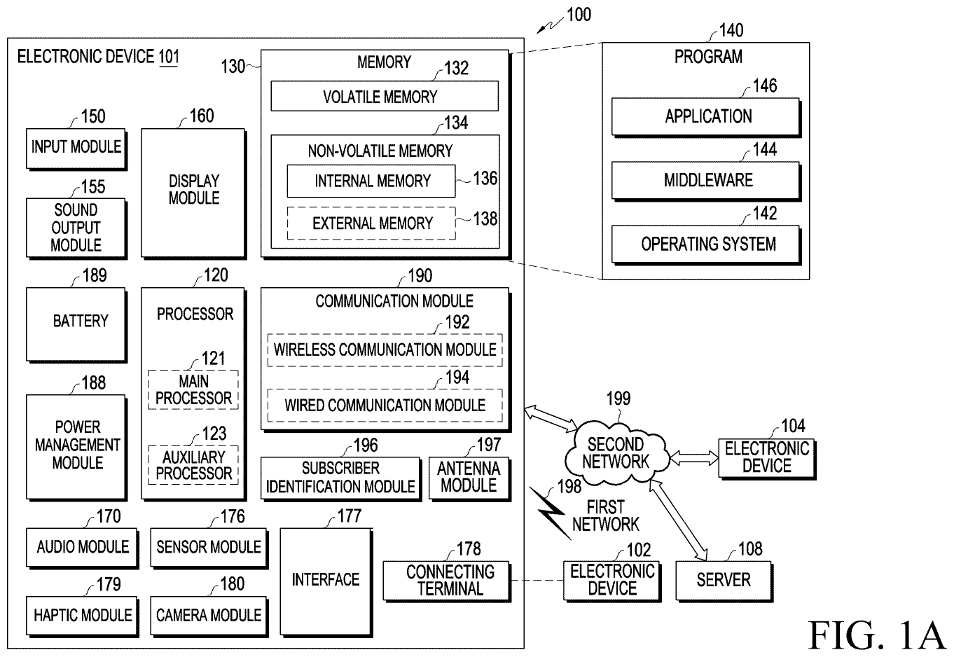

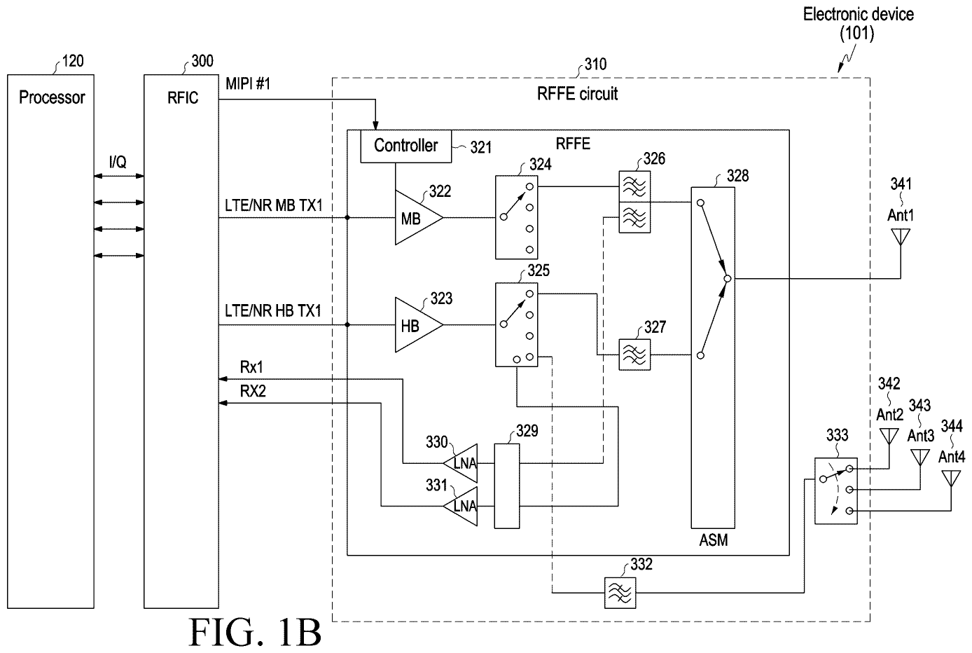

FIG. 1A is a block diagram illustrating an electronic device 101 in a network environment 100 according to an embodiment.

Referring to FIG. 1A, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control, for example, at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active (e.g., executing an application) state. According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence model is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or an external electronic device (e.g., an electronic device 102 (e.g., a speaker or a headphone)) directly or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images.

According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to an embodiment, the antenna module 197 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

FIG. 1B is a block diagram schematically illustrating an electronic device, according to an embodiment.

Referring to FIG. 1B, an electronic device 101 (e.g., an electronic device 101 in FIG. 1A) (e.g., a smart phone) may include a processor 120 (e.g., a processor 120 in FIG. 1A), a radio frequency integrated circuit (RFIC) 300, a radio frequency front end (RFFE) circuit 310, a first antenna 341, a second antenna 342, a third antenna 343, and/or a fourth antenna 344. Although FIG. 1B illustrates an example in which the electronic device 101 includes four (4) antennas including the first antenna 341, the second antenna 342, the third antenna 343, and/or the fourth antenna 344, embodiments of the present disclosure are not limited in this regard. For example, there may be no limitation on the number of antennas included in the electronic device 101.

In an embodiment, the processor 120 may include an application processor, and/or a communication processor. According to an embodiment, the electronic device 101 may further include at least one of the components described in FIG. 1A. According to an embodiment, the RFIC 300 and/or the RFFE circuit 310 may form at least a portion of a wireless communication module 192 in FIG. 1A. The processor 120 may support establishment of a communication channel in a band to be used for a wireless communication with a cellular network (e.g., a second network 199 in FIG. 1A), and a network communication via the established communication channel. According to an embodiment, the cellular network may include a 2^{nd} generation (2G) network, a 3^{rd} generation (3G) network, a 4^{th} generation (4G) network, a long term evolution (LTE) network, a 5^{th} generation (5G) network, or the like.

In an embodiment, the processor 120 may control the RFIC 300 via a control interface. In an embodiment, the processor 120 may control the RFIC 300 and the RFFE circuit 310 so that a sounding reference signal (SRS) may be transmitted via each of the first antenna 341, the second antenna 342, the third antenna 343, and/or the fourth antenna 344. In an embodiment, the processor 120 may control the RFIC 300 and the RFFE circuit 310 so that the SRS may be transmitted via each of the first antenna 341, the second antenna 342, the third antenna 343, and/or the fourth antenna 344 based on a slot structure of the wireless communication system.

In an embodiment, upon transmission, the RFIC 300 may convert a baseband signal generated by the processor 120 into a radio frequency (RF) signal of a band used in the cellular network. In an embodiment, upon reception, the RFIC 300 may convert an RF signal preprocessed via the RFFE circuit 310 after being received from the cellular network via the at least one of the first antenna 341, the second antenna 342, the third antenna 343, and/or the fourth antenna 344, into a baseband signal so that the preprocessed RF signal may be processed by the processor 120.

In an embodiment, the RFFE circuit 310 may include a controller 321, a first power amplifier (PA) 322, a second PA 323, a first switch 324, a second switch 325, a duplexer 326, a first filter 327, a first antenna switching circuit 328, a third switch 329, a first low noise amplifier (LNA) 330, a second LNA 331, a second filter 332, and/or a second antenna switching circuit 333. In an embodiment, each of the first switch 324 and the second switch 325 may be used as a transmission switch. In an embodiment, the third switch 329 may be used as a reception switch. For example, the RFFE circuit 310 may be implemented as a power amplifier with integrated low noise amplifier and duplexers (LPAMID) circuit. For example, the first antenna switching circuit 328 and the second antenna switching circuit 333 may be implemented as an antenna switching module (ASM) or a switch.

In an embodiment, the first switch 324 may connect the first PA 322 to the duplexer 326 under the control of the processor 120 and/or the RFIC 300 (or under the control of the controller 321).

In an embodiment, the second switch 325 may connect the second PA 323 to the first filter 327 or the second filter 332 under the control of the processor 120 and/or the RFIC 300 (or under the control of the controller 321).

In an embodiment, the second antenna switching circuit 333 may connect the second filter 332 to one of the second antenna 342, the third antenna 343, and/or the fourth antenna 344 under the control of the processor 120 and/or the RFIC 300 (or under the control of the controller 321).

In an embodiment, the controller 321 may control components included in the RFFE circuit 310 via an interface (e.g., a mobile industry processor interface (MIPI)) with the processor 120 and/or the RFIC 300.

In an embodiment, a signal received via the first antenna 341 may be transferred to the first antenna switching circuit 328, and the first antenna switching circuit 328 may perform a duplex operation on the signal transferred via the first antenna 341 and transfer the resulting signal to the third switch 329. The third switch 329 may connect the duplexer 326 to the first LNA 330 or the second LNA 331 under the control of the controller 321 (or under the control of the processor 120 and/or the RFIC 300).

In an embodiment, if the duplexer 326 is connected to the first LNA 330, the first LNA 330 may amplify a signal transferred from the duplexer 326 based on a set gain and then transmit it to the RFIC 300. If the duplexer 326 is connected to the second LNA 331, the second LNA 331 may amplify a signal transferred from the duplexer 326 based on a set gain and transmit the amplified signal to the RFIC 300.

Although FIG. 1B depicts the second filter 332 and the second antenna switching circuit 333 as being included in the RFFE circuit 310, embodiments of the present disclosure are not limited in this regard. For example, at least one of the second filter 332 or the second antenna switching circuit 333 may not be included in the RFFE circuit 310 and may exist separately, and/or may be included in an RFFE circuit different from the RFFE circuit 310.

The present disclosure may consider cases where an LNA may be included in an electronic device, as well as, a network (e.g., a base station) of a wireless communication system, and a structure and an operation of the LNA to be described below may be similarly applied both to a case in which the LNA is included in the electronic device and to a case in which the LNA is included in the network.

According to an embodiment, an LNA in a wireless communication system may include a first amplifier including a first transistor and amplifying a first input signal based on a first gain value to generate a first output signal.

According to an embodiment, the LNA may include a second amplifier including a plurality of second transistors and amplifying a second input signal based on a second gain value to generate a second output signal.

According to an embodiment, the LNA may include a balun connected between the first amplifier and the second amplifier, and configured to input the first output signal as a third input signal, and output the second input signal as an output signal.

According to an embodiment, the balun may include a first inductor, a second inductor, and a third inductor, and the third inductor may be connected to sources of the plurality of second transistors.

According to an embodiment, the balun may include a metal stack including a plurality of metal layers on a substrate.

According to an embodiment, the first inductor, the second inductor, and the third inductor may be disposed on a first metal layer among the plurality of metal layers, the first inductor may be disposed at an outermost portion of the first inductor, the second inductor, and the third inductor on the first metal layer, the third inductor may be disposed at an innermost portion among the first inductor, the second inductor, and the third inductor on the first metal layer, and the second inductor may be disposed between the first inductor and the third inductor.

According to an embodiment, the first inductor, the second inductor, and the third inductor may be disposed on a first metal layer among the plurality of metal layers, and the second inductor may be cross-connected to gates of the plurality of second transistors.

According to an embodiment, the first inductor, the second inductor, and the third inductor may be disposed on a first metal layer among the plurality of metal layers, and the third inductor may be cross-connected to sources of the plurality of second transistors.

According to an embodiment, the second inductor and the third inductor may be cross-connected to the second amplifier.

According to an embodiment, the third inductor connected to sources of the plurality of second transistors may be connected to a ground (GND).

According to an embodiment, the third inductor connected to sources of the plurality of second transistors may be connected to the first inductor.

According to an embodiment, the balun may further include a capacitor connected to power supply of the balun.

According to an embodiment, the first amplifier may include a single-ended amplifier, and the second amplifier may include a differential amplifier.

According to an embodiment, an electronic device in a wireless communication system may include an LNA.

According to an embodiment, the LNA may include a first amplifier including a first transistor and amplifying a first input signal based on a first gain value to generate a first output signal.

According to an embodiment, the LNA may include a second amplifier including a plurality of second transistors and amplifying a second input signal based on a second gain value to generate a second output signal.

According to an embodiment, the LNA may include a balun connected between the first amplifier and the second amplifier, and configured to input the first output signal as a third input signal, and output the second input signal as an output signal.

According to an embodiment, the balun may include a first inductor, a second inductor, and a third inductor, and the third inductor may be connected to sources of the plurality of second transistors.

According to an embodiment, the balun may include a metal stack including a plurality of metal layers on a substrate.

According to an embodiment, the first inductor, the second inductor, and the third inductor may be disposed on a first metal layer among the plurality of metal layers, the first inductor may be disposed at an outermost portion of the first inductor, the second inductor, and the third inductor on the first metal layer, the third inductor may be disposed at an innermost portion among the first inductor, the second inductor, and the third inductor on the first metal layer, and the second inductor may be disposed between the first inductor and the third inductor.

According to an embodiment, the first inductor, the second inductor, and the third inductor may be disposed on a first metal layer among the plurality of metal layers, and the second inductor may be cross-connected to gates of the plurality of second transistors.

According to an embodiment, the first inductor, the second inductor, and the third inductor may be disposed on a first metal layer among the plurality of metal layers, and the third inductor may be cross-connected to sources of the plurality of second transistors.

According to an embodiment, the second inductor and the third inductor may be cross-connected to the second amplifier.

According to an embodiment, the third inductor connected to sources of the plurality of second transistors may be connected to a ground (GND).

According to an embodiment, the third inductor connected to sources of the plurality of second transistors may be connected to the first inductor.

According to an embodiment, the balun may further include a capacitor connected to power supply of the balun.

According to an embodiment, the first amplifier may include a single-ended type of amplifier, and the second amplifier may include a differential type of amplifier.

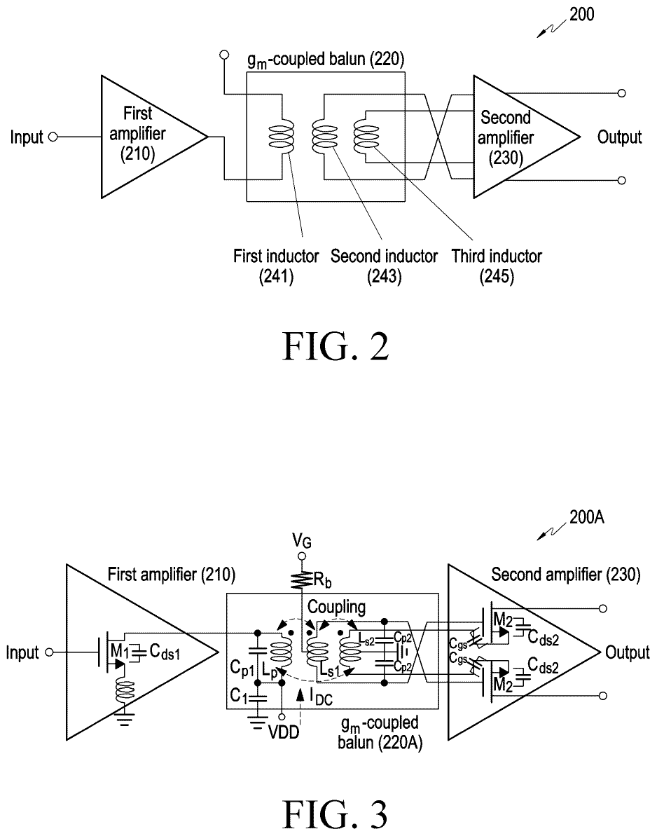

FIG. 2 is a diagram schematically illustrating an LNA in a wireless communication system, according to an embodiment.

Referring to FIG. 2, an LNA 200 may include a first amplifier 210, a gₘ-coupled balun 220, and a second amplifier 230. The LNA 200 of FIG. 2 may include and/or may be similar in many respects to the first LNA 330 or the second LNA 331 described above with reference to FIG. 1B, and may include additional features not mentioned above. Consequently, repeated descriptions of the LNA 200 described above with reference to FIG. 1B may be omitted for the sake of brevity.

In an embodiment, the first amplifier 210 may be and/or may include a single-ended (SE) amplifier, and the second amplifier 230 may be a differential amplifier. In an embodiment, the first amplifier 210 may amplify an input signal corresponding to a first gain value and output the amplified signal. In an embodiment, the second amplifier 230 may amplify an input signal corresponding to a second gain value and output the amplified signal.

In an embodiment, the gₘ-coupled balun 220 may be connected between an unbalanced circuit (e.g., the first amplifier 210) and a balanced circuit (e.g., the second amplifier 230). In an embodiment, gₘ may represent transconductance.

In an embodiment, the gₘ-coupled balun 220 may include the first inductor 241, the second inductor 243, and the third inductor 245. In an embodiment, the gₘ-coupled balun 220 may be implemented in a structure in which the first inductor 241, the second inductor 243, and the third inductor 245 are coupled to each other.

In an embodiment, the second amplifier 230 may be implemented to simultaneously (e.g., at a substantially similar and/or the same time) obtain a noise figure NF and a wideband characteristic using a relatively low input impedance. The NF may indicate how much noise is added when an input signal passes through a device or a circuit. A performance of the LNA 200 may be significantly affected by the NF and the wideband characteristic of the second amplifier 230 as well as the first amplifier 210.

Therefore, in order to potentially increase (or maximize) the performance of the LNA 200, it may be required to decrease (or minimize or prevent) loss occurring in an impedance matching process between the first amplifier 210 and the second amplifier 230. Therefore, aspects of the present disclosure may decrease (or minimize or prevent) the loss occurring in the impedance matching process between the first amplifier 210 and the second amplifier 230 while lowering input impedance of the second amplifier 230 using the gₘ-coupled balun 220. For example, by decreasing a loss that may occur in the impedance matching process between the first amplifier 210 and the second amplifier 230 while lowering the input impedance of the second amplifier 230, not only the NF and the gain characteristic of the second amplifier 230 may be improved, but also the wideband characteristic may be obtained. As a result, as the NF and the gain characteristic of the second amplifier 230 are improved and the wideband characteristic is obtained, there may also be no limitation on the bandwidth used in the LNA 200.

FIG. 3 is a diagram schematically illustrating an LNA in a wireless communication system, according to an embodiment.

Referring to FIG. 3, an LNA 200A may include a first amplifier 210, a gₘ-coupled balun 220A, and a second amplifier 230.

The LNA 200A of FIG. 3 may include and/or may be similar in many respects to the first LNA 330, the second LNA 331, and the LNA 200 described above with reference to FIGS. 1B and 2, and may include additional features not mentioned above. Furthermore, the first amplifier 210, the gₘ-coupled balun 220A, and the second amplifier 230 may include and/or may be similar in many respects to the first amplifier 210, the gₘ-coupled balun 220, and the second amplifier 230, respectively, described above with reference to FIG. 2, and may include additional features not mentioned above. Consequently, repeated descriptions of the LNA 200A described above with reference to FIGS. 1B and 2 may be omitted for the sake of brevity.

In an embodiment, the first amplifier 210 may be an SE amplifier, and the second amplifier 230 may be a differential amplifier. In an embodiment, the gₘ-coupled balun 220A may be connected between an unbalanced circuit (e.g., the first amplifier 210) and a balanced circuit (e.g., the second amplifier 230). In an embodiment, the gₘ-coupled balun 220A may include a first inductor 241 (e.g., a first inductor 241 in FIG. 2), a second inductor 243 (e.g., a second inductor 243 in FIG. 2), and a third inductor 245 (e.g., a third inductor 245 in FIG. 2). In an embodiment, the gₘ-coupled balun 220A may be implemented in a structure in which the first inductor 241, the second inductor 243, and the third inductor 245 are mutually coupled. Aspects of the present disclosure may decrease (or minimize or prevent) the loss occurring in the impedance matching process between the first amplifier 210 and the second amplifier 230 while lowering input impedance of the second amplifier 230 using the gₘ-coupled balun 220.

In an embodiment, the first amplifier 210 may be the SE amplifier for noise matching along with input matching. A first transistor M₁ may represent a transistor included in the first amplifier 210.

In an embodiment, the second amplifier 230 may be the differential amplifier having a higher gain characteristic than an SE amplifier. A second transistor M₂ may represent a transistor included in the second amplifier 230. A gate bias voltage of the second amplifier 230 may be supplied from a bias circuit, and a bias resistor Rb may be connected to the bias circuit.

The gₘ-coupled balun 220A may include three (3) inductors (e.g., a first inductor 241, a second inductor 243, and a third inductor 245). As shown in FIG. 3, Lₚ may represent the first inductor 241, Lₛ₁ may represent the second inductor 243, and Lₛ₂ may represent the third inductor 245. The first inductor 241 may be a primary inductor of the gₘ-coupled balun 220A. The first inductor 241 may supply a direct current (DC) voltage to a drain of the first transistor M₁ included in the first amplifier 210, and a first capacitor C₁ having a reactance less than or equal to a set reactance value (e.g., 1 Ohm (Ω)) may be added to a portion connected to a power supply so that the power supply may be stabilized at an operation frequency. Each of the second inductor 243 and the third inductor 245 may be a secondary inductor of the gₘ-coupled balun 220A. In an embodiment, the second inductor 243 may be connected to a gate of the second transistor M₂ of the second amplifier 230, and the third inductor 245 may be connected to a source of the second transistor M₂ of the second amplifier 230. In an embodiment, the third inductor 245 connected to the source of the second transistor M₂ of the second amplifier 230 may be cross-coupled with the second inductor 243 in consideration of constructive interference and destructive interference in an electromagnetic field, thereby decreasing the input impedance of the second amplifier 230.

In an embodiment, a capacitor Cₚ₁ and a capacitor Cₚ₂ included in the gₘ-coupled balun 220A may be used upon impedance matching between the first transistor M₁ and the second transistor M₂. In an embodiment, the capacitor Cₚ₁ and the capacitor Cₚ₂ may be matching capacitances. In an embodiment, the gₘ-coupled balun 220A may not include the capacitor Cₚ₁ and the capacitor Cₚ₂ as needed. If the gₘ-coupled balun 220A does not include the capacitor Cₚ₁ and the capacitor Cₚ₂, the capacitor Cₚ₁ and the capacitor Cₚ₂ may be replaced with capacitance C_{ds1}, capacitance C_{ds2}, and capacitance C_{gs}, which are generally parasitic capacitors of the first transistor M₁ and the second transistor M₂. For example, the capacitor Cₚ₁ and the capacitor Cₚ₂ may be replaced with the parasitic capacitor C_{ds1} of the first amplifier 210 and the parasitic capacitors C_{ds2} and C_{gs} of the second amplifier 230.

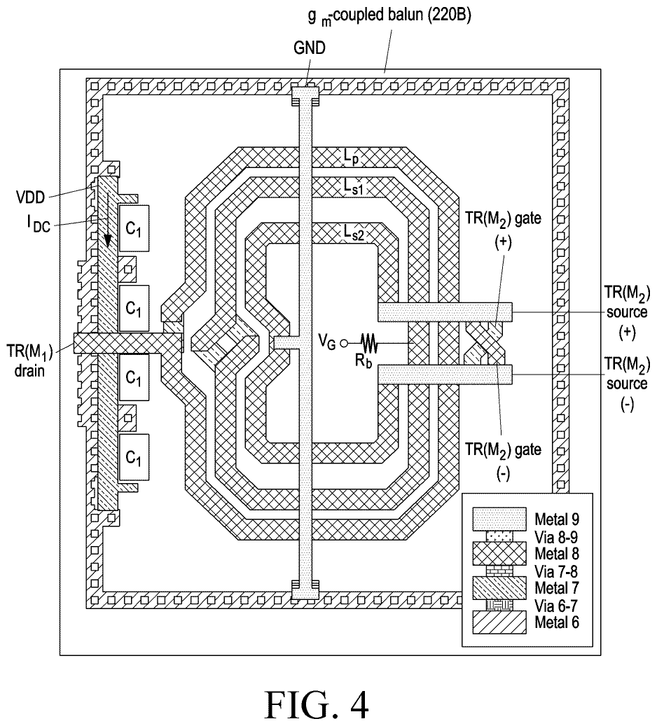

FIG. 4 is a diagram schematically illustrating a layout of a gₘ-coupled balun included in an LNA in a wireless communication system, according to an embodiment.

Referring to FIG. 4, a layout of a gₘ-coupled balun 220B is illustrated that may represent a layout on a metal structure.

The gₘ-coupled balun 220B may include and/or may be similar in many respects to the gₘ-coupled baluns 220 and 220A described above with reference to FIGS. 2 and 3, and may include additional features not mentioned above. Consequently, repeated descriptions of the gₘ-coupled balun 220B described above with reference to FIGS. 2 and 3 may be omitted for the sake of brevity.

In the gₘ-coupled balun 220B included in an LNA (e.g., the first LNA 330 or the second LNA 331 in FIG. 1B, the LNA 200 in FIG. 2, or the LNA 200A in FIG. 3), capacitors Cₚ₁ and Cₚ₂ between a first amplifier (e.g., the first amplifier 210 in FIG. 2 or FIG. 3) and a second amplifier (e.g., the second amplifier 230 in FIG. 2 or FIG. 3) may be replaced with a parasitic capacitor C_{ds1} of the first amplifier and parasitic capacitors C_{ds2} and C_{gs} of the second amplifier. In an embodiment, the capacitors Cₚ₁ and Cₚ₂ may be matching capacitors.

In an embodiment, a DC capacitor C₁ may be disposed on a path of a metal layer 7 connecting to VDD power supply. In an embodiment, in the gₘ-coupled balun 220B, a first inductor (e.g., a first inductor 241 in FIG. 2 or FIG. 3) may be disposed at an outermost portion, a second inductor (e.g., a second inductor 243 in FIG. 2 or FIG. 3) may be disposed inside the first inductor, and a third inductor (e.g., a third inductor 245 in FIG. 2 or FIG. 3) may be disposed at the innermost portion. In an embodiment, each of the first inductor, the second inductor, and the third inductor may be implemented in a form of a metal pattern. As shown in FIG. 4, Lₚ may represent the first inductor, Lₛ₁ may represent the second inductor, and Lₛ₂ may represent the third inductor.

As shown in FIG. 4, a TR (M₁) drain may represent a drain of the first transistor M₁ included in the first amplifier 210, a TR (M₂) source may represent a source of the second transistor M₂ included in the second amplifier 230, and a TR (M₂) gate may represent a gate of the second transistor M₂ included in the second amplifier 230.

As illustrated in FIG. 4, the gₘ-coupled balun 220B may be implemented in a form of a metal stack including a plurality of metal layers on a substrate. FIG. 4 illustrates a layout of the gₘ-coupled balun 220B implemented in the form of a metal stack including, for example, a metal layer 6, a metal layer 7, a metal layer 8, and a metal layer 9.

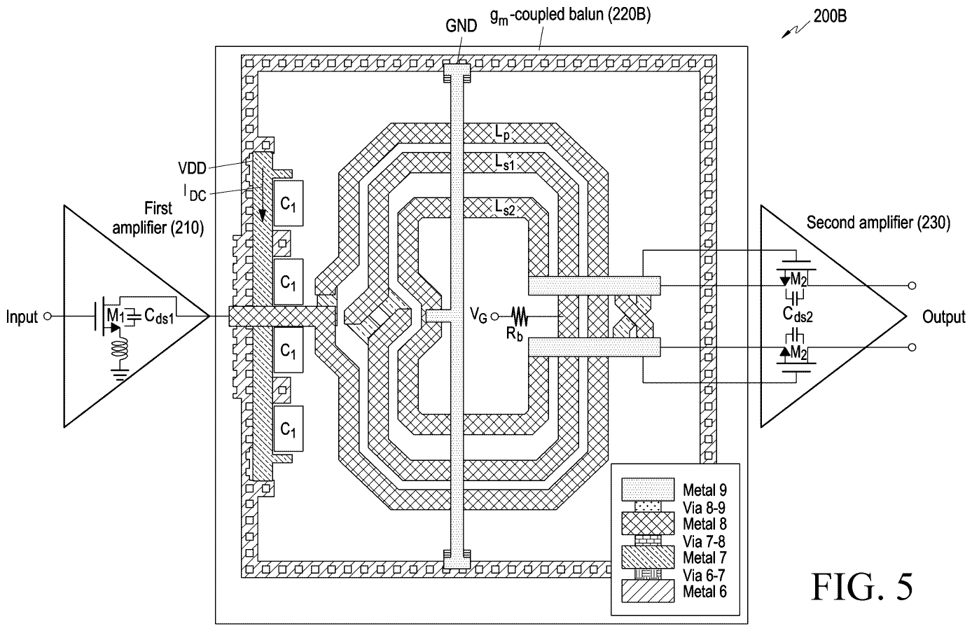

FIG. 5 is a diagram schematically illustrating an LNA in a wireless communication system, according to an embodiment.

Referring to FIG. 5, an LNA 200B may include and/or may be similar in many respects to the first LNA 330, the second LNA 331, the LNA 200, or the LNA 200A described above with reference to FIGS. 1B, 2, and 3, and may include additional features not mentioned above. For example, the LNA 200B of FIG. 5 may only differ from the LNA 200A of FIG. 3 in the manner in which the gₘ-coupled balun 220B is illustrated. That is, the gₘ-coupled balun 220A is illustrated in a form of a circuit in FIG. 3, and is illustrated in a form of a layout as described in FIG. 4 in FIG. 5.

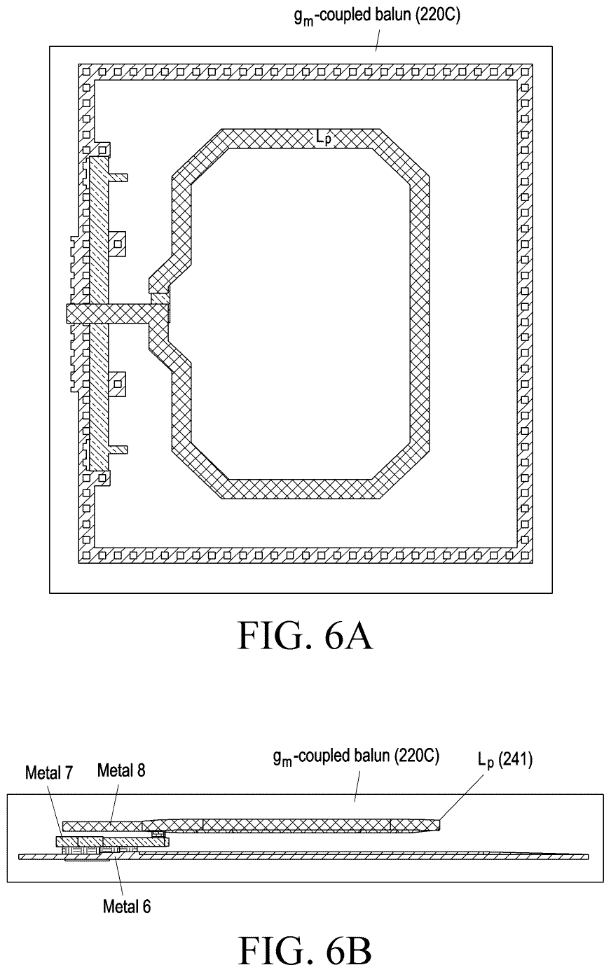

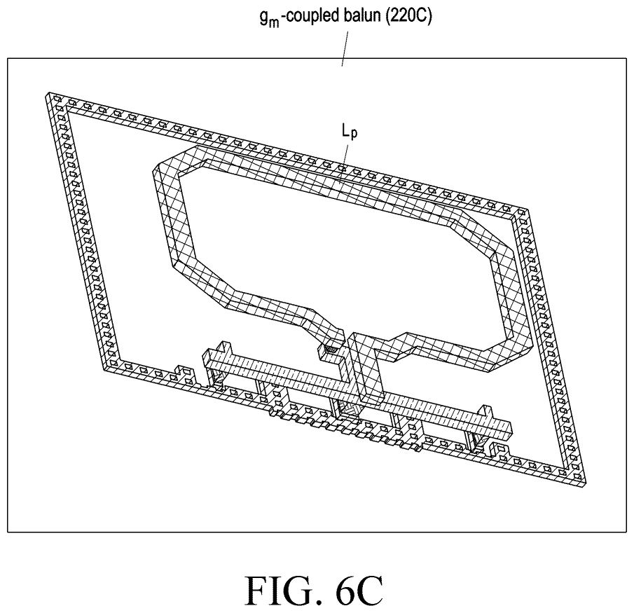

FIG. 6A is a diagram schematically illustrating a layout of a first inductor included in a gₘ-coupled balun included in an LNA, according to an embodiment.

Referring to FIG. 6A, a gₘ-coupled balun 220C may be implemented in a form of a metal stack as described in FIG. 4, and a plan view of a first inductor (e.g., the first inductor 241 in FIG. 2 or FIG. 3) is illustrated in FIG. 6A. In FIG. 6A, Lₚ may represent the first inductor 241, and may be implemented in a form of a metal pattern on a metal layer 8.

The gₘ-coupled balun 220C may include and/or may be similar in many respects to the gₘ-coupled baluns 220, 220A, and 220B described above with reference to FIGS. 2-5, and may include additional features not mentioned above. Consequently, repeated descriptions of the gₘ-coupled balun 220C described above with reference to FIGS. 2-5 may be omitted for the sake of brevity.

FIG. 6B is a diagram schematically illustrating a layout of a first inductor included in a gₘ-coupled balun included in an LNA, according to an embodiment.

Referring to FIG. 6B, the gₘ-coupled balun 220C may be implemented in a form of a metal stack as described in FIG. 4, and a front view of a first inductor (e.g., the first inductor 241 in FIG. 2 or FIG. 3) is illustrated in FIG. 6B. As shown in FIG. 6B, the first inductor 241 may be disposed on a metal layer 8. In FIG. 6B, Lₚ may represent the first inductor 241, and may be implemented in a form of a metal pattern on a metal layer 8.

As illustrated in FIG. 6B, the first inductor 241 may be disposed in a circular shape at a first position on a substrate on the metal layer 8, and may be disposed in a form of a metal pattern connected to a DC capacitor C₁ and VDD power supply present on a metal layer 7. In an embodiment, the first inductor 241 may be disposed at the outermost portion among inductors, for example, the first inductor 241, a second inductor (e.g., a second inductor 243 in FIG. 2 or FIG. 3), and a third inductor (e.g., a third inductor 245 in FIG. 2 or FIG. 3), which are arranged on the substrate.

FIG. 6C is a diagram schematically illustrating a layout of a first inductor included in a gₘ-coupled balun included in an LNA, according to an embodiment.

Referring to FIG. 6C, a gₘ-coupled balun 220C may be implemented in a form of a metal stack as described in FIG. 4, and a side view of a first inductor (e.g., the first inductor 241 in FIG. 2 or FIG. 3) is illustrated in FIG. 6C. In FIG. 6C, Lₚ may represent the first inductor 241. In FIG. 6C, Lₚ may represent the first inductor 241, and may be implemented in a form of a metal pattern on a metal layer 8.

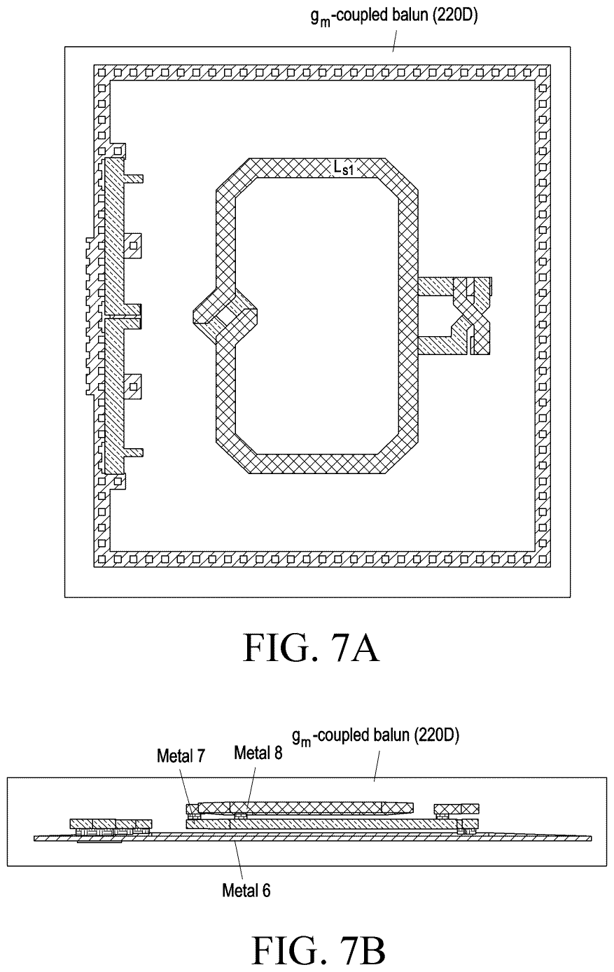

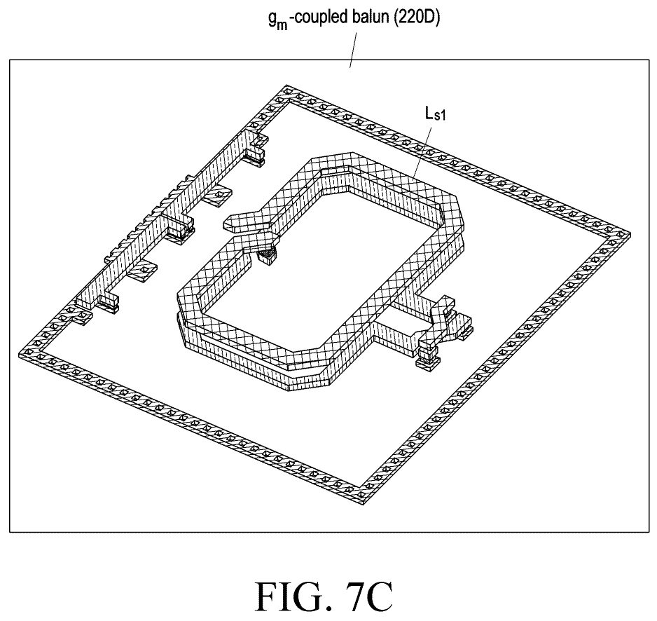

FIG. 7A is a diagram schematically illustrating a layout of a second inductor included in a gₘ-coupled balun included in an LNA, according to an embodiment.

Referring to FIG. 7A, a gₘ-coupled balun 220D may be implemented in a form of a metal stack as described in FIG. 4, and a plan view of a second inductor (e.g., the second inductor 243 in FIG. 2 or FIG. 3) is illustrated in FIG. 7A. In FIG. 7A, Lₛ₁ may represent the second inductor 243, and may be implemented in a form of a metal pattern on a metal layer 8. In an embodiment, the metal pattern corresponding to the second inductor on the metal layer 8 may overlap with a metal layer 7.

The gₘ-coupled balun 220D may include and/or may be similar in many respects to the gₘ-coupled baluns 220, 220A, 220B, and 220C described above with reference to FIGS. 2-5, 6A, 6B, and 6C, and may include additional features not mentioned above. Consequently, repeated descriptions of the gₘ-coupled balun 220D described above with reference to FIGS. 2-5, 6A, 6B, and 6C may be omitted for the sake of brevity.

FIG. 7B is a diagram schematically illustrating a layout of a second inductor included in a gₘ-coupled balun included in an LNA, according to an embodiment.

Referring to FIG. 7B, a gₘ-coupled balun 220D may be implemented in a form of a metal stack as described in FIG. 4, and a front view of a second inductor (e.g., the second inductor 243 in FIG. 2 or FIG. 3) is illustrated in FIG. 7B. As illustrated in FIG. 7B, the second inductor 243 may be disposed on a metal layer 8. In FIG. 7B, Lₛ₁ may represent the second inductor 243, and may be implemented in a form of a metal pattern on the metal layer 8. In an embodiment, the metal pattern corresponding to the second inductor on the metal layer 8 may overlap with a metal layer 7.

As illustrated in FIG. 7B, the second inductor 243 may be disposed in a circular shape at a second position on a substrate on the metal layer 8, and may be disposed in a form of a metal pattern that the second inductor 243 is cross-connected to gates of two (2) second transistors M₂ included in a second amplifier (e.g., the second amplifier 230 in FIG. 2 or FIG. 3). In an embodiment, the second inductor 243 may be disposed between a first inductor (e.g., the first inductor 241 in FIG. 2 or FIG. 3) disposed at the outermost portion among inductors, for example, the first inductor 241, the second inductor 243, and a third inductor (e.g., the third inductor 245 in FIG. 2 or FIG. 3), which may be disposed on the substrate, and the third inductor 245 may be disposed at the innermost portion among the inductors disposed on the substrate.

FIG. 7C is a diagram schematically illustrating a layout of a second inductor included in a gₘ-coupled balun included in an LNA, according to an embodiment.

Referring to FIG. 7C, a gₘ-coupled balun 220D may be implemented in a form of a metal stack as described in FIG. 4, and a side view of a second inductor (e.g., the second inductor 243 in FIG. 2 or FIG. 3) is illustrated in FIG. 7C. In FIG. 7C, Lₛ₁ may represent the second inductor 243, and may be implemented in a form of a metal pattern on a metal layer 8. In an embodiment, the metal pattern corresponding to the second inductor 243 on the metal layer 8 may overlap with a metal layer 7.

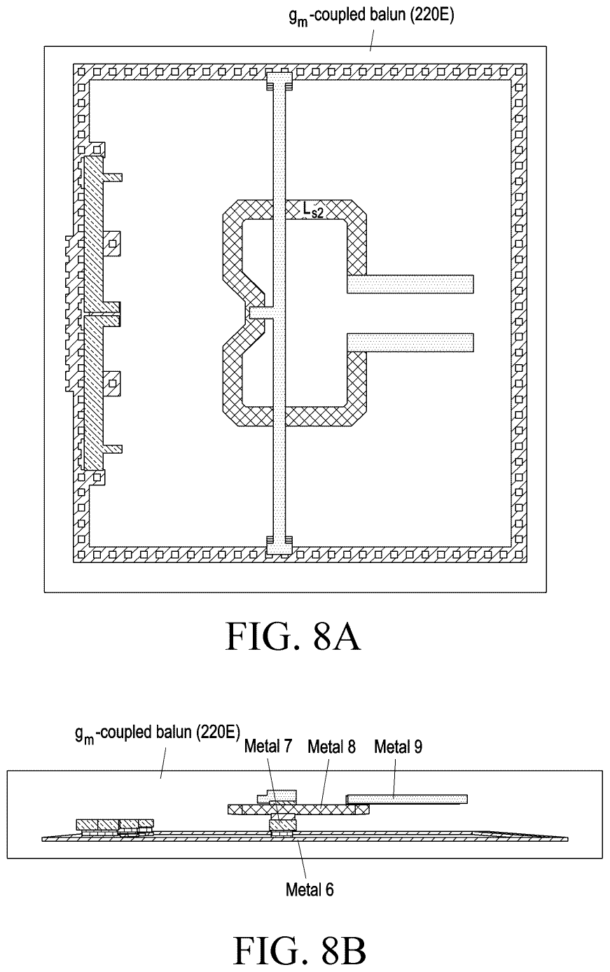

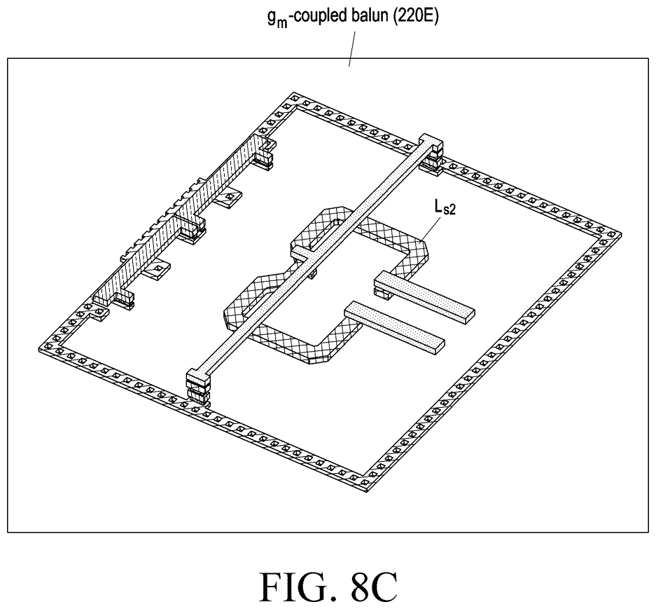

FIG. 8A is a diagram schematically illustrating a layout of a third inductor included in a gₘ-coupled balun included in an LNA, according to an embodiment.

Referring to FIG. 8A, a gₘ-coupled balun 220E may be implemented in a form of a metal stack as described in FIG. 4, and a plan view of a third inductor (e.g., the third inductor 245 in FIG. 2 or FIG. 3) is illustrated in FIG. 8A. In FIG. 8A, Lₛ₂ may represent the third inductor 245, and may be implemented in a form of a metal pattern on a metal layer 8.

The gₘ-coupled balun 220E may include and/or may be similar in many respects to the gₘ-coupled baluns 220, 220A, 220B, 220C, and 220D described above with reference to FIGS. 2-5, 6A, 6B, 6C, 7A, 7B, and 7C, and may include additional features not mentioned above. Consequently, repeated descriptions of the gₘ-coupled balun 220E described above with reference to FIGS. 2-5, 6A, 6B, 6C, 7A, 7B, and 7C may be omitted for the sake of brevity.

FIG. 8B is a diagram schematically illustrating a layout of a third inductor included in a gₘ-coupled balun included in an LNA, according to an embodiment.

Referring to FIG. 8B, a gₘ-coupled balun 220E may be implemented in a form of a metal stack as described in FIG. 4, and a front view of a third inductor (e.g., the third inductor 245 in FIG. 2 or FIG. 3) is illustrated in FIG. 8B. As illustrated in FIG. 8B, the third inductor 245 may be disposed on a metal layer 8. In FIG. 8B, Lₛ₂ may represent the third inductor 245, and may be implemented in a form of a metal pattern on the metal layer 8.

As illustrated in FIG. 8B, the third inductor 245 may be disposed in a circular shape at a third position on a substrate on the metal layer 8, and may be disposed in a form of a metal pattern that the third inductor 245 is connected to a ground (GND) present on a metal layer 9. In an embodiment, the third inductor 245 may be disposed at the innermost portion among inductors, for example, a first inductor (e.g., the first inductor 241 in FIG. 2 or FIG. 3), a second inductor (e.g., the second inductor 243 in FIG. 2 or FIG. 3), and the third inductor 245, which are disposed on the substrate.

FIG. 8C is a diagram schematically illustrating a layout of a third inductor included in a gₘ-coupled balun included in an LNA, according to an embodiment.

Referring to FIG. 8C, a gₘ-coupled balun 220E may be implemented in a form of a metal stack as described in FIG. 4, and a side view of a third inductor (e.g., the third inductor 245 in FIG. 2 or FIG. 3) is illustrated in FIG. 8C. In FIG. 8C, Lₛ₂ may represent the third inductor 245, and may be implemented in a form of a metal pattern on a metal layer 8.

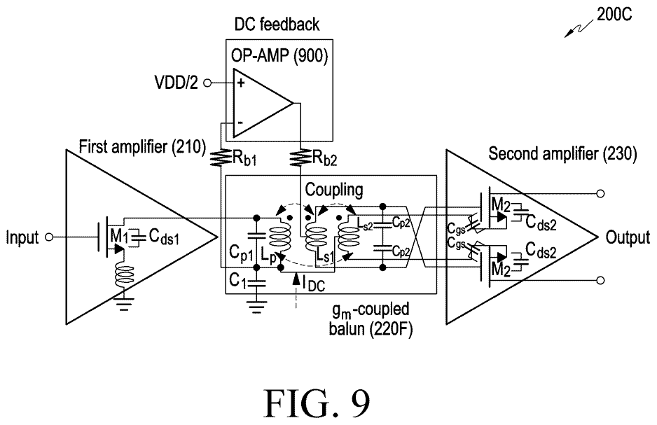

FIG. 9 is a diagram schematically illustrating an LNA in a wireless communication system, according to an embodiment.

Referring to FIG. 9, an LNA 200C may include a first amplifier 210 (e.g., the first amplifier 210 in FIG. 2 or FIG. 3), a gₘ-coupled balun 220F, a second amplifier 230 (e.g., the second amplifier 230 in FIG. 2 or FIG. 3), and an operational amplifier (OP-AMP) 900. The LNA 200C of FIG. 9 may include and/or may be similar in many respects to the first LNA 330, the second LNA 331, the LNA 200, the LNA 200A, and the LNA 200B described above with reference to FIGS. 1B, 2, 3, and 5, and may include additional features not mentioned above. In an embodiment, the LNA 200 may be an LNA in a case that a current-reuse technique is additionally applied to an LNA structure as described in FIG. 3.

The gₘ-coupled balun 220F may include and/or may be similar in many respects to the gₘ-coupled baluns 220, 220A, 220B, 220C, 220D, and 220E described above with reference to FIGS. 2-5, 6A, 6B, 6C, 7A, 7B, 7C, 8A, 8B, and 8C, and may include additional features not mentioned above. Consequently, repeated descriptions of the gₘ-coupled balun 220F described above with reference to FIGS. 2-5, 6A, 6B, 6C, 7A, 7B, 7C, 8A, 8B, and 8C may be omitted for the sake of brevity.

In an embodiment, the first amplifier 210 may be an SE amplifier, and the second amplifier 230 may be a differential amplifier. In an embodiment, a gₘ-coupled balun 220F may be connected between an unbalanced circuit (e.g., the first amplifier 210) and a balanced circuit (e.g., the second amplifier 230). In an embodiment, the gₘ-coupled balun 220F may include a first inductor 241 (e.g., the first inductor 241 in FIG. 2 or FIG. 3), a second inductor 243 (e.g., the second inductor 243 in FIG. 2 or FIG. 3), and a third inductor 245 (e.g., the third inductor 245 in FIG. 2 or FIG. 3). In an embodiment, the gₘ-coupled balun 220F may be implemented in a structure in which the first inductor 241, the second inductor 243, and the third inductor 245 are mutually coupled.

In an embodiment, the gₘ-coupled balun 220F may include three (3) inductors (e.g., a first inductor 241, a second inductor 243, and a third inductor 245). In FIG. 9, Lₚ may represent the first inductor 241, Lₛ₁ may represent the second inductor 243, and Lₛ₂ may represent the third inductor 245. The first inductor 241 may be a primary inductor of the gₘ-coupled balun 220F. The first inductor 241 may supply DC voltage to a drain of the first transistor M₁ included in the first amplifier 210, and a first capacitor C₁ having a reactance less than or equal to a set reactance value (e.g., 1Ω) may be added to a portion connected to power supply so that the power supply may be stabilized at an operation frequency. Each of the second inductor 243 and the third inductor 245 may be a secondary inductor of the gₘ-coupled balun 220F. In an embodiment, the second inductor 243 may be connected to a gate of the second transistor M₂ of the second amplifier 230, and the third inductor 245 may be connected to a source of the second transistor M₂ of the second amplifier 230. In an embodiment, the third inductor 245 connected to the source of the second transistor M₂ of the second amplifier 230 may be cross-coupled with the second inductor 243 in consideration of constructive interference and destructive interference in an electromagnetic field, thereby decreasing the input impedance of the second amplifier 230.

In an embodiment, a capacitor Cₚ₁ and a capacitor Cₚ₂ included in the gₘ-coupled balun 220F may be used upon impedance matching between the first transistor M₁ and the second transistor M₂. In an embodiment, the capacitor Cₚ₁ and the capacitor Cₚ₂ may be matching capacitances. In an embodiment, the gₘ-coupled balun 220F may not include the capacitor Cₚ₁ and the capacitor Cₚ₂ as needed. If the gₘ-coupled balun 220F does not include the capacitor Cₚ₁ and the capacitor Cₚ₂, the capacitor Cₚ₁ and the capacitor Cₚ₂ may be replaced with parasitic capacitance C_{ds1}, parasitic capacitance C_{ds2}, and parasitic capacitance C_{gs}, which may generally represent parasitic capacitors of a transistor. For example, the capacitor Cₚ₁ and the capacitor Cₚ₂ may be replaced with the parasitic capacitor C_{ds1} of the first amplifier 210 and the parasitic capacitors C_{ds2} and C_{gs} of the second amplifier 230.

In an embodiment, the third inductor Lₛ₂ 245 connected to a source of the second transistor M₂ included in the second amplifier 230 may be connected to the first inductor Lₚ 241 connected to a drain of the first transistor M₁ included in the first amplifier 210 to form a loop that is power supply voltage of the first amplifier 210 and adjusts gate bias voltage of the second amplifier 230. In such a case, a DC current relationship may be established only when a magnitude of the first transistor M₁ needs to be a set multiple (e.g., twice or two (2) times) of a magnitude of the second transistor M₂. Unlike a description in FIG. 3, a gate bias voltage of the second transistor M₂ included in the second amplifier 230 may be determined by the OP-AMP 900. In an embodiment, the OP-AMP 900 may determine the gate voltage of the second transistor M₂ included in the second amplifier 230 via a negative feedback operation which adjusts the gate bias voltage of the second transistor M₂ included in the second amplifier 230 so that the power supply voltage of the first amplifier 210 becomes half (e.g., VDD/2) of the VDD power supply voltage. In an embodiment, the gate voltage of the second transistor M₂ included in the second amplifier 230 may converge to a value obtained by adding the VDD/2 to the gate bias voltage of the first transistor M₁ included in the first amplifier 210.

In the structure of the LNA 200C as described in FIG. 9, if the bias voltage of the first amplifier 210 is adjusted, the bias voltage of the second amplifier 230 may be adjusted, thereby reducing power consumption of the LNA 200C.

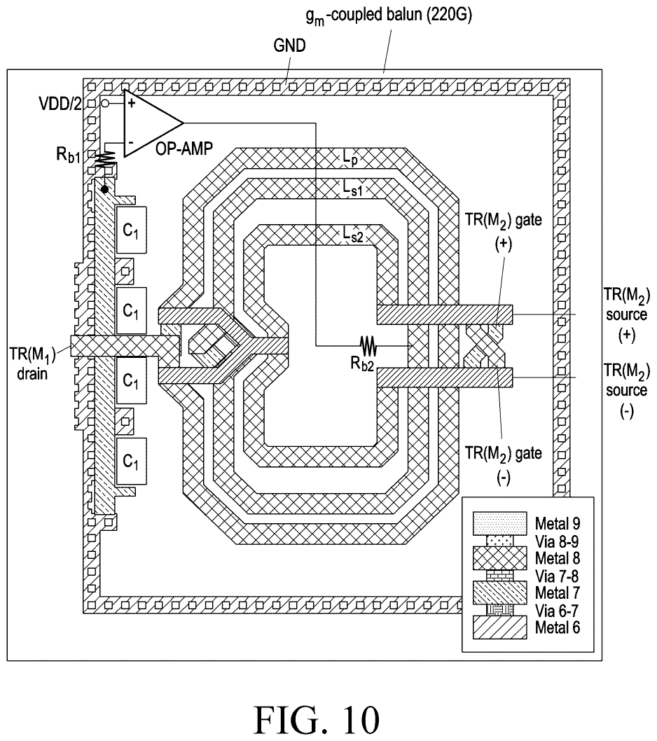

FIG. 10 is a diagram schematically illustrating a layout of a gₘ-coupled balun included in an LNA in a wireless communication system, according to an embodiment.

Referring to FIG. 10, a layout of a gₘ-coupled balun 220G may represent a layout on a metal structure. In the gₘ-coupled balun 220G included in an LNA (e.g., the first LNA 330, the second LNA 331, the LNA 200, the LNA 200A, the LNA 200B, and the LNA 200C in FIGS. 1B, 2, 3, 5, and 9), capacitors Cₚ₁ and Cₚ₂ between a first amplifier (e.g., the first amplifier 210 in FIG. 2, FIG. 3, or FIG. 9) and a second amplifier (e.g., the second amplifier 230 in FIG. 2, FIG. 3, or FIG. 9) may be replaced with a parasitic capacitor C_{ds1} of the first amplifier and parasitic capacitors C_{ds2} and C_{gs} of the second amplifier. In an embodiment, the capacitors Cₚ₁ and Cₚ₂ may be matching capacitors.

In an embodiment, a DC capacitor C₁ may be disposed on a path of a metal layer 7 connecting to VDD power supply. In an embodiment, in the gₘ-coupled balun 220G, a first inductor (e.g., the first inductor 241 in FIG. 2, FIG. 3, or FIG. 9) may be disposed at an outermost portion, a second inductor (e.g., the second inductor 243 in FIG. 2, FIG. 3, or FIG. 9) may be disposed inside the first inductor, and a third inductor (e.g., the third inductor 245 in FIG. 2, FIG. 3, or FIG. 9) may be disposed at the innermost portion. In an embodiment, each of the first inductor 241, the second inductor 243, and the third inductor 245 may be implemented in a form of a metal pattern. As shown in FIG. 10, Lₚ may represent the first inductor 241, Lₛ₁ may represent the second inductor 243, and Lₛ₂ may represent the third inductor 245.

Continuing to refer to FIG. 10, a TR (M₁) drain may represent a drain of the first transistor M₁ included in the first amplifier, a TR (M₂) source may represent a source of the second transistor M₂ included in the second amplifier, and a TR (M₂) gate may represent a gate of the second transistor M₂ included in the second amplifier.

As illustrated in FIG. 10, the gₘ-coupled balun 220G may be implemented in a form of a metal stack including a plurality of metal layers on a substrate. FIG. 10 illustrates a layout of the gₘ-coupled balun 220G implemented in the form of a metal stack including, for example, a metal layer 6, a metal layer 7, a metal layer 8, and a metal layer 9. Compared to a layout of a gₘ-coupled balun 220B illustrated in FIG. 4, the layout of the gₘ-coupled balun 220G illustrated in FIG. 10 may be in a form in which a center-tap of the third inductor Lₛ₂ 245 connected to a source of the second transistor M₂ included in the second amplifier 230 may be supplied with power supply of VDD/2 via an OP-AMP (e.g., an OP-AMP 900 in FIG. 9). In an embodiment, in order to apply a power supply reuse technology, a path through which a current flows from the second amplifier (e.g., the second amplifier 230 of FIG. 2 or FIG. 3) to the first amplifier (e.g., the first amplifier 210 in FIG. 2 or FIG. 3) may be required, and may be implemented by connecting the third inductor Lₛ₂ 245 and the first inductor Lₚ 241 using a metal layer 9.

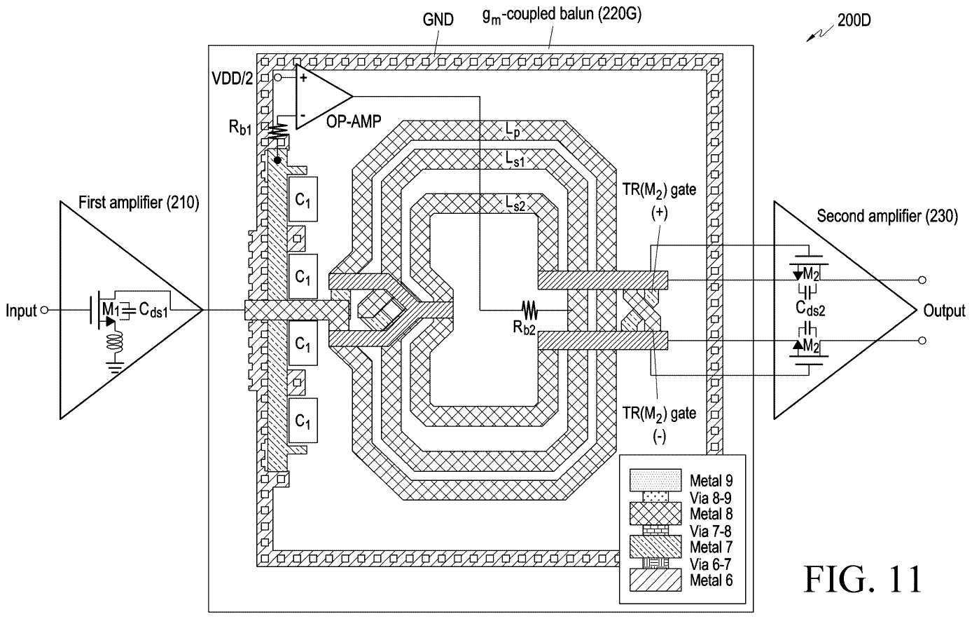

FIG. 11 is a diagram schematically illustrating an LNA in a wireless communication system, according to an embodiment.

Referring to FIG. 11, an LNA 200D may be implemented to include and/or be similar in many respects to the LNA 200C described in FIG. 9, but may be different only in that a gₘ-coupled balun 220G is illustrated in a form of a circuit in FIG. 9, and is illustrated in a form of a layout as described in FIG. 10 and FIG. 11.

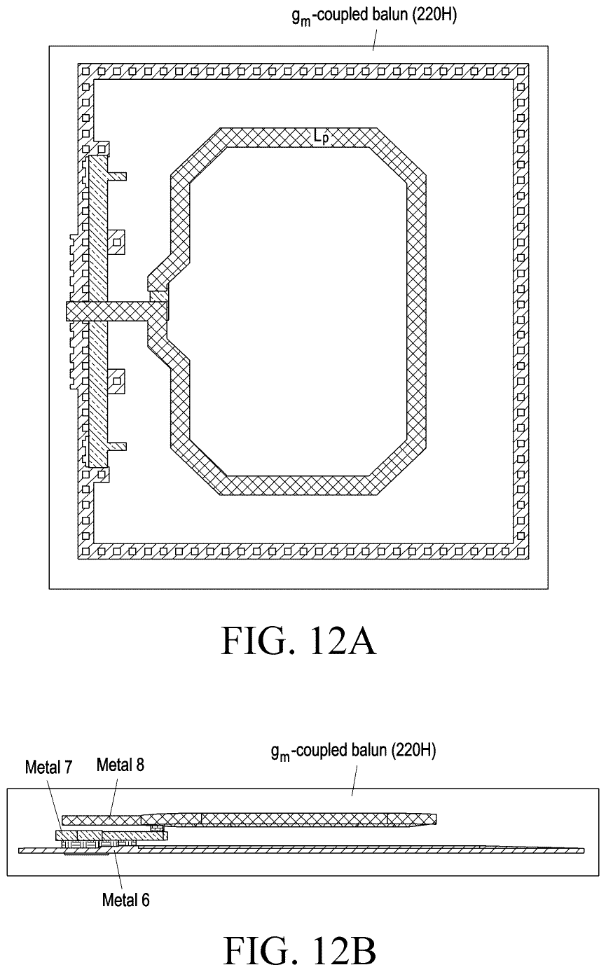

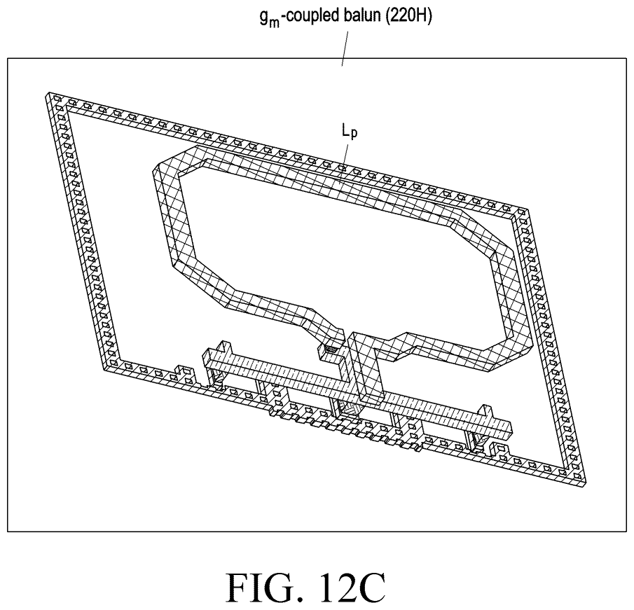

FIG. 12A is a diagram schematically illustrating a layout of a first inductor included in a gₘ-coupled balun included in an LNA, according to an embodiment.

Referring to FIG. 12A, a gₘ-coupled balun 220H may be implemented in a form of a metal stack as described in FIG. 10, and a plan view of a first inductor (e.g., the first inductor 241 in FIG. 2, FIG. 3, or FIG. 9) is illustrated in FIG. 12A. In FIG. 12A, Lₚ may represent the first inductor 241, and may be implemented in a form of a metal pattern on a metal layer 8.

The gₘ-coupled balun 220H may include and/or may be similar in many respects to the gₘ-coupled baluns 220, 220A, 220B, 220C, 220D, 220E, 220F, and 220G described above with reference to FIGS. 2-5, 6A, 6B, 6C, 7A, 7B, 7C, 8A, 8B, 8C, and 9-11, and may include additional features not mentioned above. Consequently, repeated descriptions of the gₘ-coupled balun 220H described above with reference to FIGS. 2-5, 6A, 6B, 6C, 7A, 7B, 7C, 8A, 8B, 8C, and 9-11 may be omitted for the sake of brevity.

FIG. 12B is a diagram schematically illustrating a layout of a first inductor included in a gₘ-coupled balun included in an LNA, according to an embodiment.

Referring to FIG. 12B, a gₘ-coupled balun 220H may be implemented in a form of a metal stack as described in FIG. 10, and a front view of a first inductor (e.g., a first inductor 241 in FIG. 2, FIG. 3, or FIG. 9) is illustrated in FIG. 12B. As described in FIG. 12B, the first inductor may be disposed on a metal layer 8. In FIG. 12B, Lₚ may represent the first inductor 241, and may be implemented in a form of a metal pattern on a metal layer 8.

As illustrated in FIG. 12B, the first inductor 241 may be disposed in a circular shape at a first position on a substrate on the metal layer 8, and may be disposed in a form of a metal pattern connected to a DC capacitor C₁ and VDD power supply present on a metal layer 7. In an embodiment, the first inductor 241 may be disposed at the outermost portion among inductors, for example, the first inductor 241, a second inductor 243 (e.g., the second inductor 243 in FIG. 2, FIG. 3, or FIG. 9), and a third inductor (e.g., the third inductor 245 in FIG. 2, FIG. 3, or FIG. 9), which may be arranged on the substrate.

FIG. 12C is a diagram schematically illustrating a layout of a first inductor included in a gₘ-coupled balun included in an LNA, according to an embodiment.

Referring to FIG. 12C, a gₘ-coupled balun 220H may be implemented in a form of a metal stack as described in FIG. 10, and a side view of a first inductor (e.g., a first inductor 241 in FIG. 2, FIG. 3, or FIG. 9) is illustrated in FIG. 12C. In FIG. 12C, Lₚ may represent the first inductor 241. In FIG. 12C, Lₚ may represent the first inductor 241, and may be implemented in a form of a metal pattern on a metal layer 8.

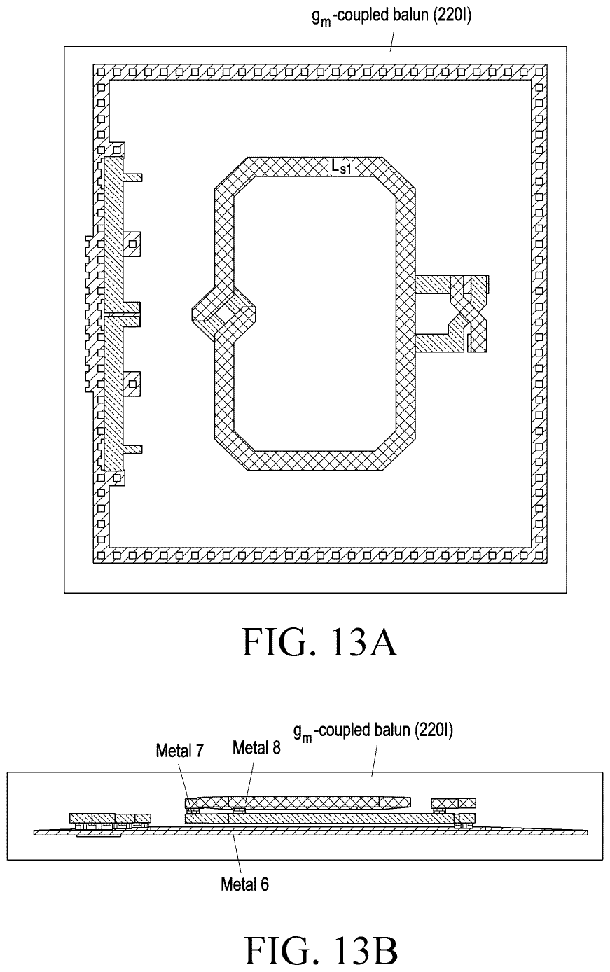

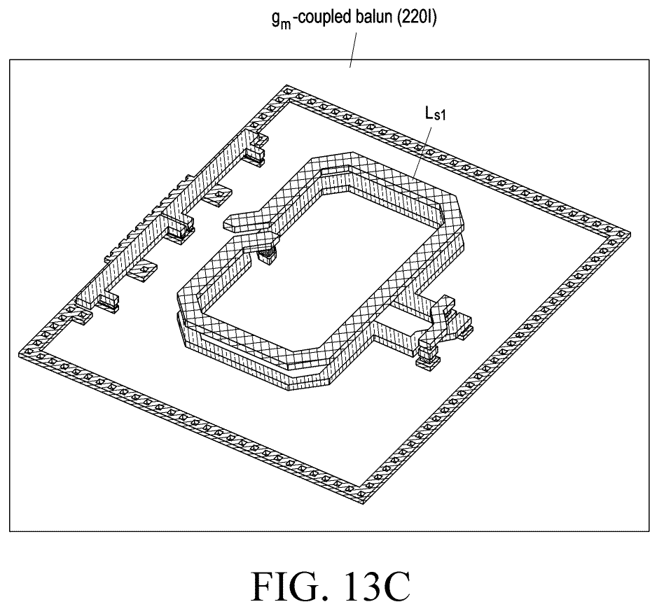

FIG. 13A is a diagram schematically illustrating a layout of a second inductor included in a gₘ-coupled balun included in an LNA, according to an embodiment.

Referring to FIG. 13A, a gₘ-coupled balun 220I may be implemented in a form of a metal stack as described in FIG. 10, and a plan view of a second inductor (e.g., a second inductor 243 in FIG. 2, FIG. 3, or FIG. 9) is illustrated in FIG. 12A. In FIG. 12A, Lₛ₁ may represent the second inductor 243, and may be implemented in a form of a metal pattern on a metal layer 8. In an embodiment, the metal pattern corresponding to the second inductor on the metal layer 8 may overlap with a metal layer 7.

FIG. 13B is a diagram schematically illustrating a layout of a second inductor included in a gₘ-coupled balun included in an LNA, according to an embodiment.

The gₘ-coupled balun 220I may include and/or may be similar in many respects to the gₘ-coupled baluns 220, 220A, 220B, 220C, 220D, 220E, 220F, 220G, and 220H described above with reference to FIGS. 2-5, 6A, 6B, 6C, 7A, 7B, 7C, 8A, 8B, 8C, 9-11, 12A, 12B, and 12C, and may include additional features not mentioned above. Consequently, repeated descriptions of the gₘ-coupled balun 220I described above with reference to FIGS. 2-5, 6A, 6B, 6C, 7A, 7B, 7C, 8A, 8B, 8C, 9-11, 12A, 12B, and 12C may be omitted for the sake of brevity.

Referring to FIG. 13B, a gₘ-coupled balun 220I may be implemented in a form of a metal stack as described in FIG. 10, and a front view of a second inductor (e.g., the second inductor 243 in FIG. 2, FIG. 3, or FIG. 9) is illustrated in FIG. 13B. As illustrated in FIG. 13B, the second inductor 243 may be disposed on a metal layer 8. In FIG. 13B, Lₛ₁ may represent the second inductor 243, and may be implemented in a form of a metal pattern on the metal layer 8. In an embodiment, the metal pattern corresponding to the second inductor on the metal layer 8 may overlap with a metal layer 7.

As illustrated in FIG. 13B, the second inductor may be disposed in a circular shape at a second position on a substrate on the metal layer 8, and may be disposed in a form of a metal pattern that the second inductor is cross-connected to gates of two (2) second transistors M₂ included in a second amplifier (e.g., the second amplifier 230 in FIG. 2, FIG. 3, or FIG. 9). In an embodiment, the second inductor 243 may be disposed between a first inductor 241 (e.g., the first inductor 241 in FIG. 2, FIG. 3, or FIG. 9) disposed at the outermost portion among inductors, for example, the first inductor 241, the second inductor 243, and a third inductor (e.g., the third inductor 245 in FIG. 2, FIG. 3, or FIG. 9), which are disposed on the substrate, and the third inductor 245 disposed at the innermost portion among the inductors disposed on the substrate.

FIG. 13C is a diagram schematically illustrating a layout of a second inductor included in a gₘ-coupled balun included in an LNA, according to an embodiment.

Referring to FIG. 13C, a gₘ-coupled balun 220I may be implemented in a form of a metal stack as described in FIG. 10, and a side view of a second inductor (e.g., the second inductor 243 in FIG. 2, FIG. 3, or FIG. 9) is illustrated in FIG. 13C. In FIG. 13C, Lₛ₁ may represent the second inductor 243, and may be implemented in a form of a metal pattern on a metal layer 8. In an embodiment, the metal pattern corresponding to the second inductor 243 on the metal layer 8 may overlap with a metal layer 7.

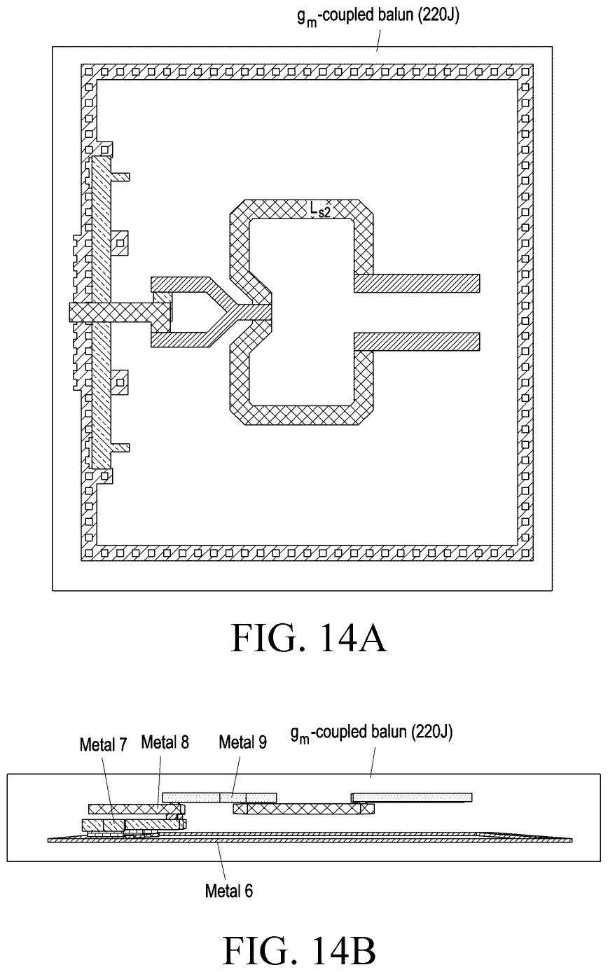

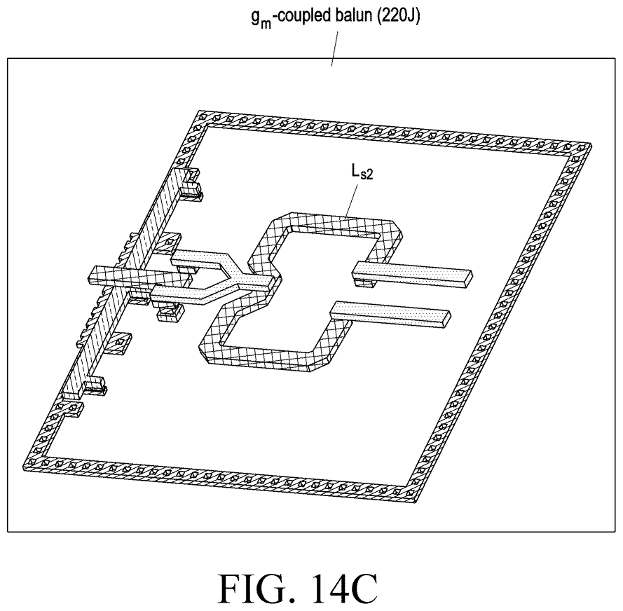

FIG. 14A is a diagram schematically illustrating a layout of a third inductor included in a gₘ-coupled balun included in an LNA, according to an embodiment.

Referring to FIG. 14A, a gₘ-coupled balun 220J may be implemented in a form of a metal stack as described in FIG. 10, and a plan view of a third inductor (e.g., the third inductor 245 in FIG. 2, FIG. 3, or FIG. 9) is illustrated in FIG. 14A. In FIG. 14A, Lₛ₂ may represent the third inductor 245, and may be implemented in a form of a metal pattern on a metal layer 8.

The gₘ-coupled balun 220J may include and/or may be similar in many respects to the gₘ-coupled baluns 220, 220A, 220B, 220C, 220D, 220E, 220F, 220G, 220H, and 220I described above with reference to FIGS. 2-5, 6A, 6B, 6C, 7A, 7B, 7C, 8A, 8B, 8C, 9-11, 12A, 12B, 12C, 13A, 13B, and 13C and may include additional features not mentioned above. Consequently, repeated descriptions of the gₘ-coupled balun 220J described above with reference to FIGS. 2-5, 6A, 6B, 6C, 7A, 7B, 7C, 8A, 8B, 8C, 9-11, 12A, 12B, 12C, 13A, 13B, and 13C may be omitted for the sake of brevity.

FIG. 14B is a diagram schematically illustrating a layout of a third inductor included in a gₘ-coupled balun included in an LNA, according to an embodiment.

Referring to FIG. 14B, a gₘ-coupled balun 220J may be implemented in a form of a metal stack as described in FIG. 10, and a front view of a third inductor (e.g., the third inductor 245 in FIG. 2, FIG. 3, or FIG. 9) is illustrated in FIG. 14B. As illustrated in FIG. 14B, the third inductor 245 may be disposed on a metal layer 8. In FIG. 14B, Lₛ₂ may represent the third inductor 245, and may be implemented in a form of a metal pattern on the metal layer 8.

As illustrated in FIG. 14B, the third inductor 245 may be disposed in a circular shape at a third position on a substrate on the metal layer 8, and may be disposed in a form of a metal pattern that the third inductor 245 is connected to a first inductor 241 connected to a drain of the first transistor M₁ included in the first amplifier 210 via a metal layer 9 to form a current path. In an embodiment, the third inductor 245 may be disposed at the innermost portion among inductors, for example, a first inductor (e.g., the first inductor 241 in FIG. 2, FIG. 3, or FIG. 9), a second inductor (e.g., the second inductor 243 in FIG. 2, FIG. 3, or FIG. 9), and the third inductor 245, which are disposed on the substrate.

FIG. 14C is a diagram schematically illustrating a layout of a third inductor included in a gₘ-coupled balun included in an LNA, according to an embodiment.

Referring to FIG. 14C, a gₘ-coupled balun 220J may be implemented in a form of a metal stack as described in FIG. 10, and a side view of a third inductor (e.g., the third inductor 245 in FIG. 2, FIG. 3, or FIG. 9) is illustrated in FIG. 14C. In FIG. 14C, Lₛ₂ may represent the third inductor 245, and may be implemented in a form of a metal pattern on a metal layer 8.

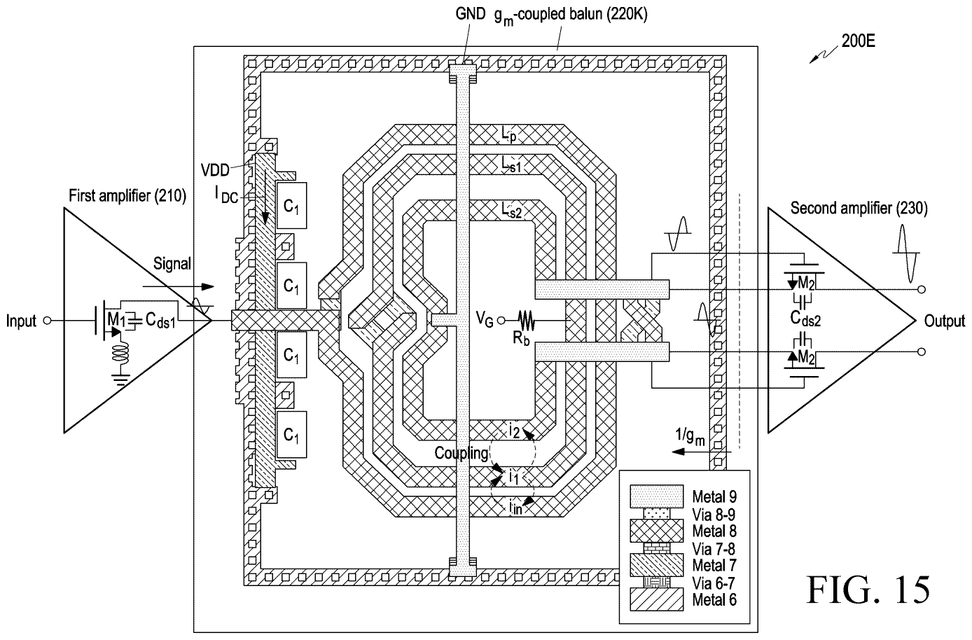

FIG. 15 is a diagram illustrating an operation of an LNA in a wireless communication system, according to an embodiment.

Referring to FIG. 15, an LNA 200E may include a first amplifier (e.g., the first amplifier 210 in FIG. 2, FIG. 3, or FIG. 9), a gₘ-coupled balun 220K, and a second amplifier (e.g., the second amplifier 230 in FIG. 2, FIG. 3, or FIG. 9). In an embodiment, the gₘ-coupled balun 220K may include a first inductor (e.g., the first inductor 241 in FIG. 2, FIG. 3, or FIG. 9), a second inductor (e.g., the second inductor 243 in FIG. 2, FIG. 3, or FIG. 9), and a third inductor (e.g., the third inductor 245 in FIG. 2, FIG. 3, or FIG. 9). In an embodiment, the gₘ-coupled balun 220K may be implemented in a structure in which the first inductor 241, the second inductor 243, and the third inductor 245 are mutually coupled.

A structure of the LNA 200E illustrated in FIG. 15 may be implemented to include and/or may to be similar in many respects to the first LNA 330, the second LNA 331, the LNAs 200, 200A, 200B, 200C, and 200D described above with reference to FIGS. 1B, 2, 3, 5, 9, and 11, and may include additional features not mentioned above. Consequently, repeated descriptions of the LNA 200E described above with reference to FIGS. 1B and 2 may be omitted for the sake of brevity.

The LNA 200E, according to an embodiment, may have a low input impedance characteristic and a high isolation characteristic, and an operation in which the low input impedance characteristic is achieved in a case that the LNA 200E is used, according to an embodiment, is described with reference to FIG. 15.

In an embodiment, if input voltage V_{G} is supplied constantly, a current i₂ may flow from a drain to a source of the second transistor M₂ included in the second amplifier 230, so that an amplifier operation may be performed. In this state, if a signal passes from an input terminal to an output terminal of the LNA 200, a current iᵢₙ may flow in a first inductor Lₚ. A current induced from the first inductor Lₚ may flow as a current i₁ in an opposite direction of a second inductor Lₛ₁, and a current induced from a second inductor Lₛ₁ may flow as a current in an opposite direction of a third inductor Lₛ₂. In such a case, the current flowing in the third inductor Lₛ₂ may be a current which may be obtained by adding the current induced from the second inductor Lₛ₁ and a current i₂ which may flow in a transistor, and as a result, amount of the current flowing in the third inductor Lₛ₂ may increase.

As expressed in the following Equation 1, if current amount increases while input voltage is constant, an input impedance is lowered, so an impedance viewed from a source side of the transistor may have a value proportional to 1/gₘ. Accordingly, as a phase of a signal inputted to the LNA 200E is repeatedly inverted via the inductors Lₚ, Lₛ₁, and Lₛ₂ and the transistors M₁ and M₂ included in the LNA 200, the LNA 200E may finally output an amplified signal.

$${Z}_{IN} = \frac{V}{I} = R + j ω L + \frac{1}{j ω {C}_{gs}} = \frac{1}{{g}_{m}} + j ( ω L - \frac{1}{ω {C}_{gs}} ) \qquad [ Equation 1 ]$$

In Equation 1, ZIN may represent input impedance, L may represent Lₛ₁ or Lₛ₂, and Lₛ₁=Lₛ₂. In Equation 1, C_{gs} may represent a capacitor between the gate and the source of transistor M₂, and gₘ may represent transconductance.

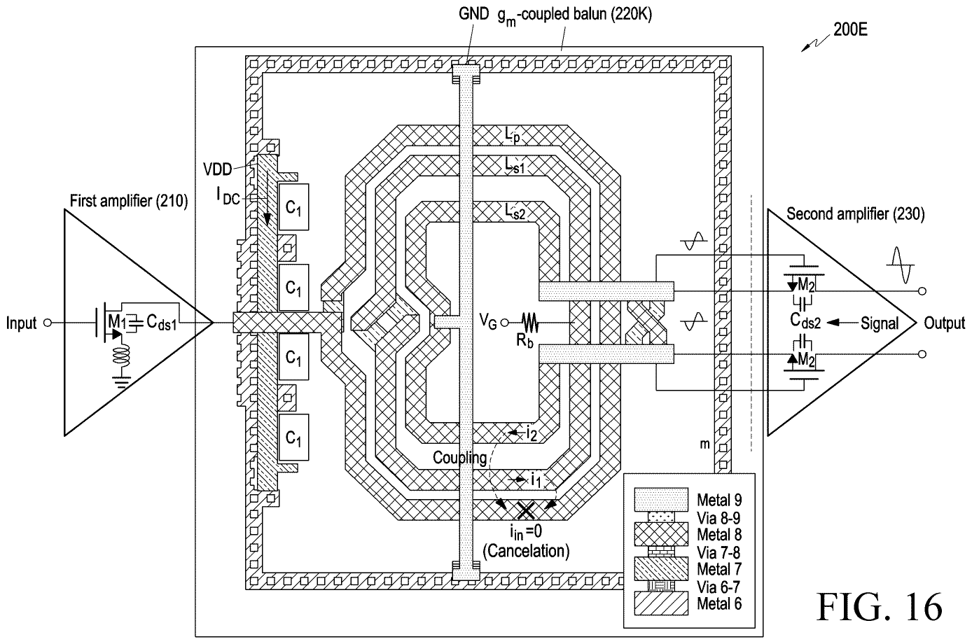

FIG. 16 is a diagram illustrating an operation of an LNA in a wireless communication system, according to an embodiment.

Referring to FIG. 16, the LNA 200E may include a first amplifier (e.g., the first amplifier 210 in FIG. 2, FIG. 3, or FIG. 9), the gₘ-coupled balun 220K, and a second amplifier (e.g., the second amplifier 230 in FIG. 2, FIG. 3, or FIG. 9). In an embodiment, the gₘ-coupled balun 220K may include a first inductor (e.g., the first inductor 241 in FIG. 2, FIG. 3, or FIG. 9), a second inductor (e.g., the second inductor 243 in FIG. 2, FIG. 3, or FIG. 9), and a third inductor (e.g., the third inductor 245 in FIG. 2, FIG. 3, or FIG. 9). In an embodiment, the gₘ-coupled balun 220K may be implemented in a structure in which the first inductor 241, the second inductor 243, and the third inductor 245 are mutually coupled.

The LNA 200E, according to an embodiment, may have a low input impedance characteristic and a high isolation characteristic, and an operation in which the high isolation characteristic is achieved in a case that the LNA 200 is used, according to an embodiment, is described with reference to FIG. 16.

In an embodiment, if input voltage V_{G} is supplied constantly, a current i₂ may flow from a drain to a source of a transistor M₂ included in the second amplifier 230, so that an amplifier operation may be performed. In this state, if a signal passes from an output terminal to an input terminal of the LNA 200E, currents i₁ and i₂ flowing in inductors Lₛ₁ and Lₛ₂ may be induced in a first inductor Lₚ. In this case, currents induced in the first inductor Lₚ may flow in opposite directions, thereby being offset. For example, the current i₁ flowing in the second inductor Lₛ₁ and the current i₂ flowing in the third inductor Lₛ₂ may be induced in the first inductor Lₚ, respectively, and the current induced in the first inductor Lₚ from the current i₁ flowing in the second inductor Lₛ₁ and the current induced in the first inductor Lₚ from the current i₂ flowing in the third inductor Lₛ₂ flow in opposite directions and then may offset each other. Therefore, a current may not flow in the first inductor Lₚ. Therefore, since a signal is not induced from an output terminal to an input terminal of the LNA 200E, the LNA 200E may stably operate, and thus, a signal inputted to the LNA 200E may be normally amplified.

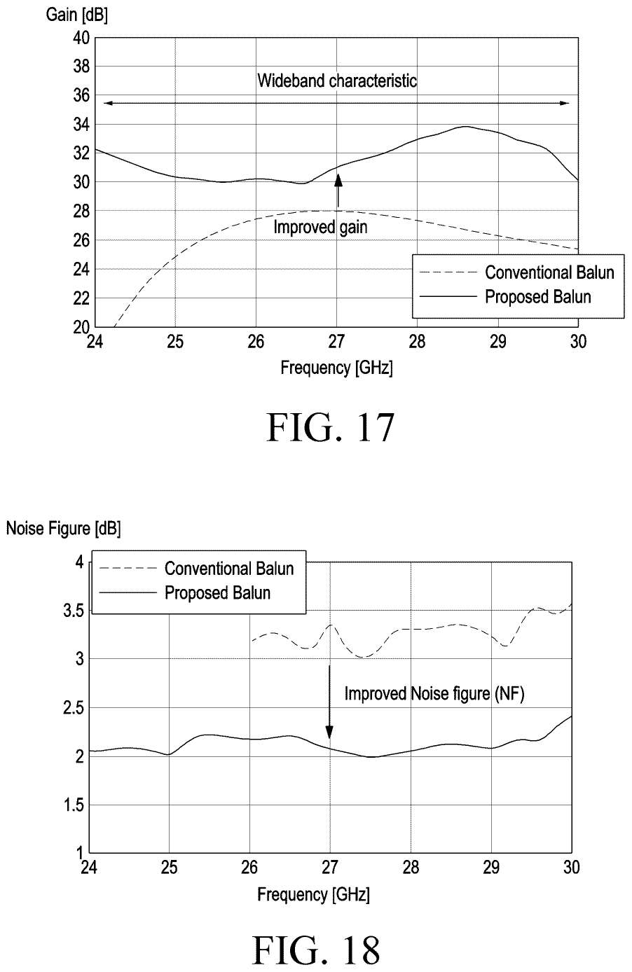

FIG. 17 is a diagram illustrating a gain of an LNA in a wireless communication system, according to an embodiment.

Referring to FIG. 17, a gain characteristic (represented by a solid line) with a wideband characteristic of an LNA (e.g., the LNAs 200, 200A, 200B, 200C, 200D, and 200E in FIGS. 2, 3, 5, 9, 11, and 15) including a gₘ-coupled balun (e.g., the gₘ-coupled baluns 220, 220A, 220B, 220C, 220D, 220E, 220F, 220G, 220H, 220I, 220J, and 220K of FIGS. 2-5, 6A, 6B, 6C, 7A, 7B, 7C, 8A, 8B, 8C, 9-11, 12A, 12B, 12C, 13A, 13B, 13C, 14A, 14B, 14C, 15 and 16), according to an embodiment, may be improved when compared to a gain characteristic of an LNA including a related balun (represented by a dashed line).

FIG. 18 is a diagram illustrating an NF of an LNA in a wireless communication system, according to an embodiment.

Referring to FIG. 18, an NF characteristic (represented by a solid line) of an LNA (e.g., the LNAs 200, 200A, 200B, 200C, 200D, and 200E in FIGS. 2, 3, 5, 9, 11, and 15) including a gₘ-coupled balun (e.g., the gₘ-coupled baluns 220, 220A, 220B, 220C, 220D, 220E, 220F, 220G, 220H, 220I, 220J, and 220K of FIGS. 2-5, 6A, 6B, 6C, 7A, 7B, 7C, 8A, 8B, 8C, 9-11, 12A, 12B, 12C, 13A, 13B, 13C, 14A, 14B, 14C, 15 and 16), according to an embodiment, may be improved when compared to NF characteristic (represented by a dashed line) of an LNA including a related balun. In addition, if a current reuse technology is applied, an effect of reducing power consumption of the LNA may also be obtained.

The electronic device according to an embodiment may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that an embodiment of the disclosure and the terms used therein are not intended to limit the technological features set forth herein to an embodiment and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1^{st}” and “2^{nd},” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with an embodiment of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or two or more functions. For example, according to an embodiment, the module may be implemented in a form of an application-specific integrated circuit (ASIC).

An embodiment as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to an embodiment of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to an embodiment, each component (e.g., a module or a program) of the above-described components may include a single entity or multiple entities, and some of the multiple entities may be separately disposed in different components. According to an embodiment, one or more of the above-described components or operations may be omitted, or one or more other components or operations may be added. Alternatively or additionally, a plurality of components (e.g., modules or programs) may be integrated into a single component. In such a case, the integrated component may still perform one or more functions of each of the plurality of components in the same or similar manner as they are performed by a corresponding one of the plurality of components before the integration. According to an embodiment, operations performed by the module, the program, or another component may be carried out sequentially, in parallel, repeatedly, or heuristically, or one or more of the operations may be executed in a different order or omitted, or one or more other operations may be added.

While the present disclosure has been described with reference to illustrative embodiments, this description is not intended to be construed in a limiting sense. Various modifications and combinations of the illustrative embodiments, as well as other embodiments of the present disclosure, may be apparent to persons skilled in the art upon reference to the description. It is therefore intended that the appended claims encompass any such modifications or embodiments.

What is claimed is:

1. A low noise amplifier (LNA) in a wireless communication system, the LNA comprising:
a first amplifier comprising a first transistor and configured to amplify a first input signal based on a first gain to generate a first output signal;
a second amplifier comprising a plurality of second transistors and configured to amplify a second input signal based on a second gain to generate a second output signal; and
a balun coupled between the first amplifier and the second amplifier, and configured to input the first output signal and to output the second input signal,
wherein the balun comprises a first inductor, a second inductor, and a third inductor, and
wherein the third inductor is coupled with sources of the plurality of second transistors.

2. The LNA of claim 1, wherein the balun further comprises a metal stack comprising a plurality of metal layers on a substrate.

3. The LNA of claim 2, wherein the first inductor, the second inductor, and the third inductor are disposed on a first metal layer of the plurality of metal layers,
wherein the first inductor is disposed at an outermost portion of the first metal layer among the first inductor, the second inductor, and the third inductor,
wherein the third inductor is disposed at an innermost portion of the first metal layer among the first inductor, the second inductor, and the third inductor, and
wherein the second inductor is between the first inductor and the third inductor.

4. The LNA of claim 2, wherein the first inductor, the second inductor, and the third inductor are disposed on a first metal layer of the plurality of metal layers, and
wherein the second inductor is cross-coupled with gates of the plurality of second transistors.

5. The LNA of claim 2, wherein the first inductor, the second inductor, and the third inductor are disposed on a first metal layer of the plurality of metal layers, and
wherein the third inductor is cross-coupled with the sources of the plurality of second transistors.

6. The LNA of claim 1, wherein the second inductor and the third inductor are cross-coupled with the second amplifier.

7. The LNA of claim 2, wherein the third inductor is coupled with a ground.

8. The LNA of claim 2, wherein the third inductor is coupled with the first inductor.

9. The LNA of claim 1, wherein the balun further comprises:
a power supply; and
a capacitor coupled with the power supply.

10. The LNA of claim 1, wherein the first amplifier comprises a single-ended amplifier, and
wherein the second amplifier comprises a differential amplifier.

11. An electronic device in a wireless communication system, the electronic device comprising:
a plurality of antennas;
a processor configured to process received signals; and
a radio frequency front end (RFFE) circuit comprising at least one low noise amplifier (LNA) and configured to:
transmit a sounding reference signal (SRS) via each antenna of the plurality of antennas;
convert at least one radio frequency (RF) signal, received via one or more antennas of the plurality of antennas, into a baseband signal;
amplify the baseband signal using the at least one LNA; and
transfer, to the processor, the amplified baseband signal to perform additional processing of the amplified baseband signal,
wherein each LNA of the at least one LNA comprises:
a first amplifier comprising a first transistor and configured to amplify a first input signal based on a first gain to generate a first output signal;
a second amplifier comprising a plurality of second transistors and configured to amplify a second input signal based on a second gain to generate a second output signal; and
a balun coupled between the first amplifier and the second amplifier, and configured to input the first output signal and to output the second input signal,
wherein the balun comprises a first inductor, a second inductor, and a third inductor, and
wherein the third inductor is coupled with sources of the plurality of second transistors.

12. The electronic device of claim 11, wherein the balun further comprises a metal stack comprising a plurality of metal layers on a substrate.

13. The electronic device of claim 12, wherein the first inductor, the second inductor, and the third inductor are disposed on a first metal layer of the plurality of metal layers,
wherein the first inductor is disposed at an outermost portion of the first metal layer among the first inductor, the second inductor, and the third inductor,
wherein the third inductor is disposed at an innermost portion of the first metal layer among the first inductor, the second inductor, and the third inductor, and
wherein the second inductor is between the first inductor and the third inductor.

14. The electronic device of claim 12, wherein the first inductor, the second inductor, and the third inductor are disposed on a first metal layer of the plurality of metal layers, and
wherein the second inductor is cross-coupled with gates of the plurality of second transistors.

15. The electronic device of claim 12, wherein the first inductor, the second inductor, and the third inductor are disposed on a first metal layer of the plurality of metal layers, and
wherein the third inductor is cross-coupled with the sources of the plurality of second transistors.

16. The electronic device of claim 11, wherein the second inductor and the third inductor are cross-coupled with the second amplifier.

17. The electronic device of claim 12, wherein the third inductor is coupled with a ground.

18. The electronic device of claim 12, wherein the third inductor is coupled with the first inductor.

19. The electronic device of claim 11, wherein the balun further comprises:
a power supply; and
a capacitor coupled with the power supply.

20. The electronic device of claim 11, wherein the first amplifier comprises a single-ended amplifier, and
wherein the second amplifier comprises a differential amplifier.
